(19) United States
(12) Patent Application Publication
(10) Pub. No.: US 2024/0268161 A1
(43) Pub. Date: Aug. 8, 2024

(54) DISPLAY DEVICE AND METHOD OF FABRICATING THE SAME

(71) Applicant: Samsung Display Co., LTD., Yongin-si (KR)

(72) Inventors: Seung Bo SHIM, Yongin-si (KR); Hyo Jung KIM, Yongin-si (KR); Ji Hyeon SON, Yongin-si (KR); Jeong Yong LEE, Yongin-si (KR); Yoo Young PARK, Yongin-si (KR); Ji Myoung SEO, Yongin-si (KR)

(73) Assignee: Samsung Display Co., LTD., Yongin-si (KR)

(21) Appl. No.: 18/490,891

(22) Filed: Oct. 20, 2023

(30) Foreign Application Priority Data
Feb. 6, 2023 (KR) 10-2023-0015611

(51) Int. Cl. H10K 59/123; H01L 29/786; H10K 59/12; H10K 71/16; H10K 71/60

(52) U.S. Cl. CPC H10K 59/123; H01L 29/7869; H01L 29/78696; H10K 59/1201; H10K 71/166; H10K 71/60

(57) ABSTRACT

A display device includes a first transistor, a pixel electrode electrically connected to the first transistor, and a second transistor electrically connected to the first transistor. A nitrogen content per unit area of an active layer of the second transistor is greater than a nitrogen content per unit area of an active layer of the first transistor.

### CROSS REFERENCE TO RELATED APPLICATION(S)

This application claims priority to and benefits of Korean Patent Application No. 10-2023-0015611 under 35 U.S.C. § 119, filed on Feb. 6, 2023 in the Korean Intellectual Property Office, the entire contents of which is incorporated herein by reference.

### BACKGROUND

### 1. Technical Field

The disclosure relates to a display device in which an active layer comprising different materials can be formed via a single mask process, and a method of fabricating the same.

### 2. Description of the Related Art

An organic light-emitting display apparatus includes display elements having luminance varying depending on electric current, for example, organic light-emitting diodes.

### SUMMARY

Aspects of the disclosure provide a display device in which an active layer including different materials can be formed via a single mask process, and a method of fabricating the same.

According to an embodiment of the disclosure, a display device may include a first transistor, a pixel electrode electrically connected to the first transistor, and a second transistor electrically connected to the first transistor. A nitrogen content per unit area of an active layer of the second transistor may be greater than a nitrogen content per unit area of an active layer of the first transistor.

In an embodiment, the active layer may include a first channel region of the first transistor and a second channel region of the second transistor. A nitrogen content per unit area of the second channel region may be greater than a nitrogen content per unit area of the second channel region.

In an embodiment, the active layer may include a first source region of the first transistor, a first drain region of the first transistor, a second source region of the second transistor, and a second drain region of the second transistor. A nitrogen content per unit area of the second source region may be greater than a nitrogen content per unit area of the first source region.

In an embodiment, a nitrogen content per unit area of the second drain region may be greater than a nitrogen content per unit area of the first drain region.

In an embodiment, the active layer may include a first active layer overlapping a first gate electrode of the first transistor in plan view, and a second active layer overlapping a second gate electrode of the second transistor in plan view. A nitrogen content per unit area of the second active layer may be greater than the nitrogen content per unit area of the first active layer.

In an embodiment, the first active layer and the second active layer may be disposed on a same layer.

In an embodiment, a threshold voltage of the second transistor may be greater than a threshold voltage of the first transistor.

In an embodiment, the active layer further may include at least one of indium-gallium-zinc oxide and indium-gallium-zinc-tin oxide.

According to an embodiment of the disclosure, a display device may include an active layer, a first transistor including a first gate electrode overlapping a first channel region of the active layer in plan view, a second transistor including a second gate electrode overlapping a second channel region of the active layer in plan view, and a pixel electrode electrically connected to the first transistor. A nitrogen content per unit area of the second channel region may be greater than a nitrogen content per unit area of the first channel region.

In an embodiment, the active layer may include a first source region of the first transistor, a first drain region of the first transistor, a second source region of the second transistor, and a second drain region of the second transistor. A nitrogen content per unit area of the second source region may be greater than a nitrogen content per unit area of the first source region.

In an embodiment, a nitrogen content per unit area of the second drain region may be greater than a nitrogen content per unit area of the first drain region.

According to an embodiment of the disclosure, a method of fabricating a display device may include forming an active material layer on a substrate including a first area and a second area, forming a first photoresist pattern having a larger thickness in the first area among the first and second areas and on the active material layer, patterning the active material layer using the first photoresist pattern as a mask to form active layers, forming a second photoresist pattern by removing a part of the first photoresist pattern in line with the second area, providing nitrogen to a part of the active layer exposed in the second area using the second photoresist pattern as a mask, forming a first transistor including a gate electrode overlapping the active layer of the first area in plan view, forming a second transistor including a gate electrode overlapping the active layer of the second area in plan view, and forming a pixel electrode electrically connected to the first transistor.

In an embodiment, the providing of nitrogen may include providing nitrogen to the part of the active layer of the second area exposed by the second photoresist pattern using N₂O as a plasma gas.

In an embodiment, the active layer of the first area may include a channel region of the first transistor, a source region of the first transistor, and a drain region of the first transistor.

In an embodiment, the active layer of the second area may include a channel region of the second transistor, a source region of the second transistor, and a drain region of the second transistor.

According to an embodiment of the disclosure, the method may include preparing a substrate including a second area including first sub-areas and second sub-areas, and a first area, forming an active material layer on the substrate, forming a first photoresist pattern on the active material layer, the first photoresist pattern having a larger thickness is formed in the first area and the first sub-areas among the first area, the first sub-areas and the second sub-areas, patterning the active material layer using the first photoresist pattern as a mask to form active layers, forming a second photoresist pattern by removing parts of the first photoresist pattern in line with the second area and the second sub-area, providing nitrogen to parts of the active layer exposed in the second area and the second sub-areas using the second photoresist pattern as a mask, forming a first transistor including a gate electrode overlapping the active layer of the first area in plan view, forming a second transistor including a gate electrode overlapping the active layer of the second area in plan view, and forming a pixel electrode electrically connected to the first transistor.

In an embodiment, the method may further include after the providing of nitrogen, removing the second photoresist pattern, and annealing the substrate including the active layer.

In an embodiment, the active layer of the first area may include a channel region of the first transistor, a source region of the first transistor, and a drain region of the first transistor.

In an embodiment, the active layer of the second area may include a channel region of the second transistor, a source region of the second transistor, and a drain region of the second transistor.

According to an embodiment of the disclosure, a method of fabricating a display device may include forming a first active layer containing nitrogen on a substrate, forming a second active layer on the substrate, forming a first transistor including a gate electrode overlapping the second active layer in plan view, forming a second transistor including a gate electrode overlapping the first active layer in plan view, and forming a pixel electrode electrically connected to the first transistor.

In an embodiment, the first active layer may include a channel region of the second transistor, a source region of the second transistor, and a drain region of the second transistor.

In an embodiment, the second active layer may include a channel region of the first transistor, a source region of the first transistor, and a drain region of the first transistor.

According to an embodiment of the disclosure, an active layer including different materials can be formed via a single mask process using a half-tone mask. Accordingly, it may be possible to form the active layer having the different materials via a single mask process so that the active layer of a switching transistor contains more nitrogen than the active layer of a driving transistor.

In this manner, it may be possible to fabricate a display device that can suppress leakage current of the switching transistor without compromising the current driving capability of the driving transistor, which requires high reliability, while reducing the number of processing steps.

Aspects of the disclosure are not limited to those mentioned above and additional aspects of the disclosure, which are not mentioned herein, will be clearly understood by those skilled in the art from the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view showing a display device according to an embodiment of the disclosure.

FIG. 2 is a schematic cross-sectional view showing a display device according to an embodiment of the disclosure.

FIG. 3 is a schematic plan view showing a display unit of a display device according to an embodiment of the disclosure.

FIG. 4 is a schematic block diagram illustrating a display panel and a display driver according to an embodiment of the disclosure.

FIG. 5 is a schematic diagram of a circuit of a pixel of a display device according to an embodiment of the disclosure.

FIGS. A6 and 6B are schematic plan views of a pixel array of a display device including the pixel circuit of FIG. 5 according to an embodiment of the disclosure.

FIG. 7 is a schematic plan view selectively showing only a first conductive layer among the elements of FIG. A6.

FIG. 8 is a schematic plan view selectively showing only a second conductive layer among the elements of FIG. 6A.

FIG. 9 is a schematic plan view selectively showing only a third conductive layer among the elements of FIG. 6A.

FIG. 10 is a schematic plan view selectively showing only a fourth conductive layer among the elements of FIG. 6A.

FIG. 11 is a schematic plan view selectively showing only a fifth conductive layer among the elements of FIG. 6A.

FIG. 12 is a schematic plan view selectively showing only second and third conductive layers among the elements of FIG. 6A.

FIG. 13 is a schematic plan view selectively showing only first and second conductive layers among the elements of FIG. 6A.

FIG. 14 is a schematic cross-sectional view taken along line I-I′ of FIG. 6A.

FIG. 15 is a schematic cross-sectional view showing a structure of a display device according to an embodiment of the disclosure.

FIGS. 16 to 19 are schematic cross-sectional views illustrating structures of light-emitting elements according to embodiments.

FIG. 20 is a schematic cross-sectional view showing an example of the organic light-emitting diode of FIG. 18.

FIG. 21 is a schematic cross-sectional view showing an example of the organic light-emitting diode of FIG. 19.

FIG. 22 is a schematic cross-sectional view showing a structure of a pixel of a display device according to an embodiment of the disclosure.

FIGS. 23 to 35 are schematic cross-sectional views showing processing steps for illustrating a method of fabricating a display device according to an embodiment of the disclosure.

FIGS. 36 to 46 are schematic cross-sectional views showing processing steps for illustrating a method of fabricating a display device according to an embodiment of the disclosure.

FIG. 47 is a schematic plan view of a pixel array of a display device including the pixel circuits of FIG. 5 according to an embodiment of the disclosure.

FIG. 48 is a schematic cross-sectional view taken along line II-II′ of FIG. 47.

FIGS. 49 to 53 are schematic cross-sectional views showing processing steps for illustrating a method of fabricating a display device according to an embodiment of the disclosure.

FIG. 54 is a schematic graph for illustrating the effects of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

It will be understood that when a layer is referred to as being “on” another layer or substrate, it can be directly on the other layer or substrate, or intervening layers may also be present.

Each of the features of the various embodiments of the disclosure may be combined or combined with each other, in part or in whole, and technically various interlocking and driving are possible. Each embodiment may be implemented independently of each other or may be implemented together in an association.

It will be understood that, although the terms “first,” “second,” “third,” etc. may be used herein to describe various elements, these elements should not be limited by these terms. These terms are used to distinguish one element from another element. For example, “a first element,” could be termed “a second element” or “a third element” without departing from the teachings herein. Similarly, “the second element” or “the third element” may be alternately termed.

It will be understood that when an element is referred to as being “connected” or “coupled” to another element, it can be directly connected or coupled to the element or intervening elements may be present. In contrast, when an element is referred to as being “directly connected” or “directly coupled” to another element, there may be no intervening elements present.

It will be understood that the terms “connected to” or “coupled to” may include a physical and/or electrical connection or coupling.

The terms used herein are for the purpose of describing particular embodiments only and are not intended to limit the disclosure. As used herein, the singular expression includes the plural expression unless the context clearly indicates otherwise. It will be understood that the terms “includes” or “have”, when used in this specification, specify the presence of stated feature, number, step, operation, element, component, or their combination but do not preclude the presence or addition of one or more other features, numbers, steps, operations, elements, components or their combinations.

Unless otherwise defined or implied, all terms (including technical and scientific terms) used herein have the same meaning as commonly understood by those having ordinary skill in the art to which the disclosure belongs. It will be understood that terms, such as those defined in commonly used dictionaries, will not be interpreted in an idealized or overly formal sense unless expressly so defined herein.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Terms such as “units,” “ . . . ors(ers),” “blocks,” and “modules”, which are used throughout the disclosure, may mean a unit for processing at least one function or operation. For example, the terms may mean hardware components such as software, FPGA or ASIC, but are not limited to software or hardware. The terms such as “units,” “ . . . ors(ers),” “blocks,” and “modules” may be configured to be in an addressable storage medium, or may be configured to reproduce one or more processors.

Therefore, as an example, “units,” “ . . . ors(ers),” “blocks,” and “modules” include components such as software components, object-oriented software components, class components, and task components, processes, functions, attributes, procedures, subroutines, segments of program code, drivers, firmware, microcode, circuitry, data, databases, data structures, tables, arrays, and parameters. The functions provided in the components and “units,” “ . . . ors(ers),” “blocks,” and “modules” may be combined into a smaller number of components, “units,” “ . . . ors(ers),” “blocks,” and “modules” or divided into additional components and “units,” “ . . . ors(ers),” “blocks,” and “modules”.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

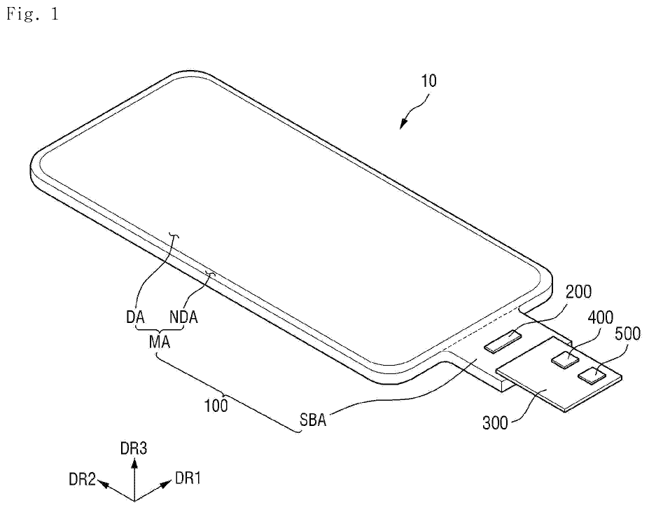

FIG. 1 is a schematic perspective view showing a display device according to an embodiment of the disclosure.

Referring to FIG. 1, a display device 10 may be employed by portable electronic devices such as a mobile phone, a smart phone, a tablet PC, a mobile communications terminal, an electronic notebook, an electronic book, a portable multimedia player (PMP), a navigation device, and/or an ultra mobile PC (UMPC). For example, the display device 10 may be used as a display unit of a television, a laptop computer, a monitor, an electronic billboard, or an Internet of Things (IoT) apparatus. As another example, the display device 10 may be applied to wearable devices such as a smart watch, a watch phone, a glasses-type display, and/or a head-mounted display (HMD) device.

The display device 10 may have a shape similarly to a quadrangular shape when viewed from the top. For example, the display device 10 may have a shape similar to a rectangle having shorter sides in the first direction DR1 and longer sides in the second direction DR2. The corners where the shorter sides in the first direction DR1 meet the longer sides in the second direction DR2 may be rounded with a predetermined or selected curvature or may be a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300, a touch driver 400, and a power supply unit 500.

The display panel 100 may include a main area MA and a subsidiary area SBA.

The main area MA may include a display area DA having pixels for displaying images, and a non-display area NDA located around the display area DA. The display area DA may emit light from multiple emission areas or multiple opening areas. For example, the display panel 100 may include a pixel circuit PC including switching elements, a pixel-defining layer that defines the emission areas or the opening areas, and a self-light-emitting element.

For example, the self-light-emitting element may include, but is not limited to, at least one of an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be disposed on the outer side of the display area DA. The non-display area NDA may be defined as the edge area of the main area MA of the display panel 100. The non-display area NDA may include a gate driver (not shown) that applies gate signals to gate lines, and fan-out lines (not shown) that connect the display driver 200 with the display area DA.

The subsidiary area SBA may be extended from a side of the main area MA. The subsidiary area SUB may include a flexible material that can be bent, folded, and/or rolled. For example, in case that the subsidiary area SBA is bent, the subsidiary area SBA may overlap the main area MA in the thickness direction (e.g., third direction DR3). The subsidiary area SBA may include pads connected to the display driver 200 and the circuit board 300. Optionally, the subsidiary area SBA may be eliminated, and the display driver 200 and the pads may be disposed in the non-display area NDA.

The display driver 200 may output signals and voltages for driving the display panel 100. The display driver 200 may supply data voltages to data lines DL. The display driver 200 may apply a supply voltage to a voltage line and may supply a gate control signal to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap the main area MA in the thickness direction (third direction DR3) in case that the the subsidiary area SBA is bent. As another example, the display driver 200 may be mounted on the circuit board 300.

The circuit board 300 may be attached on the pads of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be electrically connected to a touch sensing unit of the display panel 100. The touch driver 400 may supply a touch driving signal to multiple touch electrodes of the touch sensing unit and may sense a change in the capacitance between the touch electrodes. For example, the touch driving signal may be a pulse signal having a predetermined or selected frequency. The touch driver 400 may determine whether there is an input and may find the coordinates of the input based on the amount of the change in the capacitance between the touch electrodes. The touch driver 400 may be implemented as an integrated circuit (IC).

The power supply unit 500 may be disposed on the circuit board 300 to apply a supply voltage to the display drivers 200 and the display panel 100. The power supply unit 500 may generate a first driving voltage to supply it to a first driving voltage line VDL, may generate an initialization voltage to supply it to an initialization voltage line VIL, and may generate a common voltage to supply it to a common electrode shared by the light-emitting elements of multiple pixels For example, the first driving voltage may be a high-level voltage for driving the light-emitting elements, and the common voltage and a second driving voltage may be low-level voltages for driving the light-emitting elements.

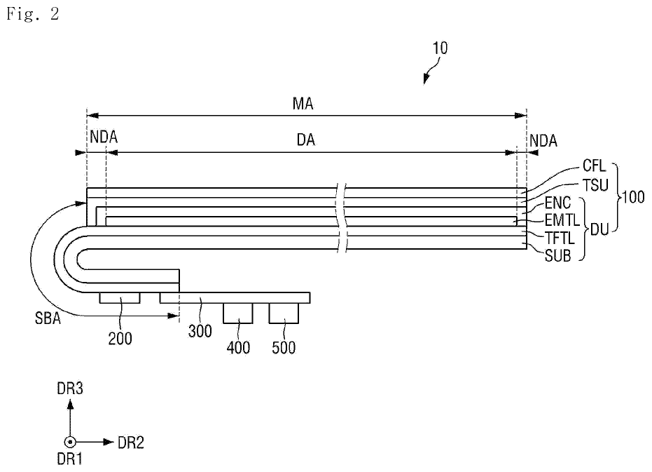

FIG. 2 is a schematic cross-sectional view showing a display device according to an embodiment of the disclosure.

Referring to FIG. 2, the display panel 100 may include a display unit DU, a touch sensing unit TSU, and a color filter layer CFL. The display unit DU may include a substrate SUB, a thin-film transistor layer TFTL, an emission layer EMTL and an encapsulation layer ENC.

The substrate SUB may be a base substrate or a base member. The substrate SUB may be a flexible substrate that can be bent, folded, and/or rolled. For example, the substrate SUB may include, but is not limited to, a polymer resin such as polyimide PI. As another example, the substrate SUB may include a glass material or a metal material.

The thin-film transistor layer TFTL may be disposed on the substrate SUB. The thin-film transistor layer TFTL may include multiple thin-film transistors forming pixel circuits PC of pixels. The thin-film transistor layer TFTL may include gate lines, data lines DL, voltage lines, gate control lines, fan-out lines for connecting the display driver 200 with the data lines DL, and lead lines for connecting the display driver 200 with the pads. Each of the thin-film transistors may include a semiconductor region, a source electrode, a drain electrode, and a gate electrode. For example, in case that the gate driver is formed on a side of the non-display area NDA of the display panel 100, the gate driver may include thin-film transistors.

The thin-film transistor layer TFTL may be disposed in the display area DA, the non-display area NDA and the subsidiary area SBA. The thin-film transistors in each of the pixels, the gate lines, the data lines DL, and the voltage lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

The emission layer EMTL may be disposed on the thin-film transistor layer TFTL. The emission layer EMTL may include multiple light-emitting elements in each of which a pixel electrode, an emissive layer and a common electrode are stacked on one another sequentially to emit light, and a pixel-defining film for defining the pixels. The light-emitting elements in the emission layer EMTL may be disposed in the display area DA.

For example, the emissive layer may be an organic emissive layer containing an organic material. The emissive layer may include a hole transporting layer, an organic light-emitting layer and an electron transporting layer. In case that the pixel electrode receives a voltage and the common electrode receives a cathode voltage through the thin-film transistors in the thin-film transistor layer TFTL, the holes and electrons may move to the organic light-emitting layer through the hole transporting layer and the electron transporting layer, respectively, such that they combine in the organic light-emitting layer to emit light. For example, the pixel electrode may be an anode electrode while the common electrode may be a cathode electrode. It is, however, to be understood that the disclosure is not limited thereto.

As another example, the light-emitting elements may include quantum-dot light-emitting diodes each including a quantum-dot emissive layer, inorganic light-emitting diodes each including an inorganic semiconductor, and/or micro light-emitting diodes.

The encapsulation layer ENC may cover the upper and side surfaces of the emission layer EMTL, and can protect the emission layer EMTL. The encapsulation layer ENC may include at least one inorganic layer and at least one organic layer for encapsulating the emission layer EMTL.

The touch sensing unit TSU may be disposed on the encapsulation layer ENC. The touch sensing unit TSU may include multiple touch electrodes for sensing a user's touch by capacitive sensing, and touch lines connecting the touch electrodes with the touch driver 400. For example, the touch sensing unit TSU may sense a user's touch by mutual capacitance sensing or self-capacitance sensing.

As another example, the touch sensing unit TSU may be disposed on a separate substrate disposed on the display unit DU. The substrate supporting the touch sensing unit TSU may be a base member encapsulating the display unit DU.

The touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include multiple color filters associated with the emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is disposed directly on the touch sensing unit TSU, the display device 10 may require no separate substrate for the color filter layer CFL. Therefore, the thickness of the display device 10 can be relatively reduced.

The subsidiary area SBA of the display panel 100 may be extended from a side of the main area MA. The subsidiary area SBA may include a flexible material that can be bent, folded, or rolled. For example, in case that the subsidiary area SBA is bent, the subsidiary area SBA may overlap the main area MA in the thickness direction (third direction DR3). The subsidiary area SBA may include pads electrically connected to the display driver 200 and the circuit board 300.

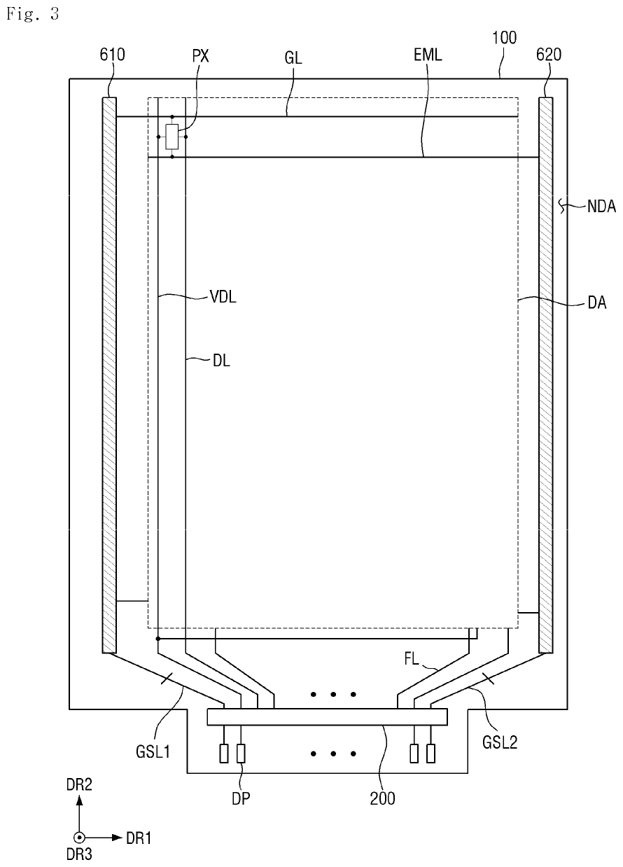

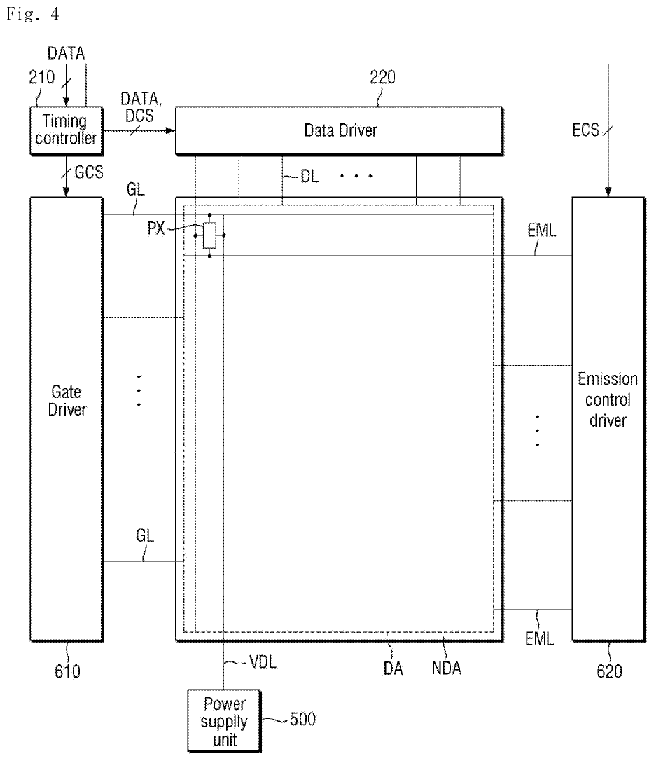

FIG. 3 is a schematic plan view showing a display unit of a display device according to an embodiment of the disclosure. FIG. 4 is a schematic block diagram illustrating a display panel and a display driver according to an embodiment of the disclosure.

Referring to FIGS. 3 and 4, the display panel 100 may include the display area DA and the non-display area NDA.

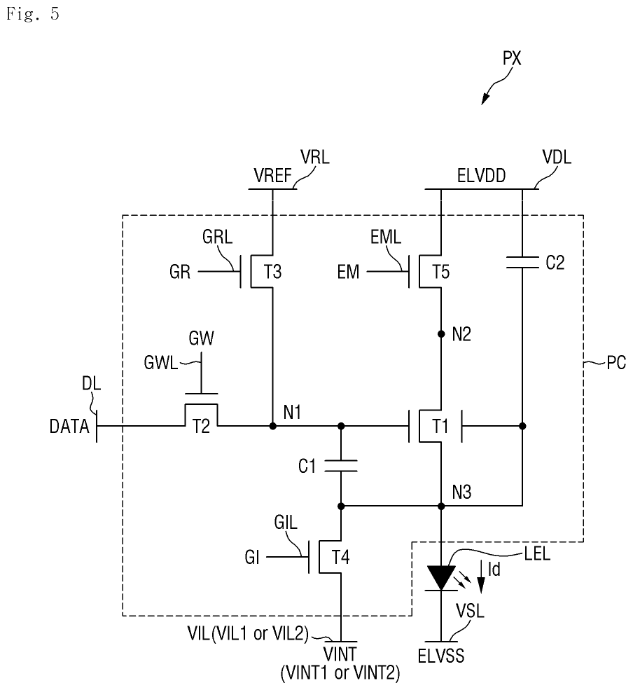

The display area DA may include multiple pixels PX, multiple first driving voltage lines VDL connected to the pixels PX, multiple gate lines GL of multiple second driving voltage lines VSL (see FIG. 5), emission control lines EML, and multiple data lines DL.

Each of the pixels PX may be connected to a gate line GL, a data line DL, an emission control line EML, a first driving voltage line VDL, and a second driving voltage line VSL. Each of the pixels PX may include at least one transistor, a light-emitting element, and a capacitor.

The gate lines GL may be extended in the first direction DR1 and may be spaced apart from one another in the second direction DR2 intersecting the first direction DR1. The gate lines GL may be arranged in the second direction DR2. The gate lines GL may sequentially supply gate signals to the pixels PX.

The emission control lines EML may be extended in the first direction DR1 and may be spaced apart from one another in the second direction DR2. The emission control lines EML may be arranged along the second direction DR2. The emission control lines EML may sequentially supply emission control signals to the pixels PX.

The data lines DL may be extended in the second direction DR2 and may be spaced apart from one another in the first direction DR1. The data lines DL may be arranged along the first direction DR1. The data lines DL may supply data voltages to the pixels PX. The data voltage may determine the luminance of each of the pixels PX.

The first driving voltage lines VDL may be extended in the second direction DR2 and may be spaced apart from one another in the first direction DR1. The first driving voltage lines VDL may be arranged along the first direction DR1. The first driving voltage lines VDL may supply the first driving voltage to the pixels PX. The first driving voltage may be a high-level voltage for driving light-emitting elements of the pixels PX.

The non-display area NDA may surround the display area DA. The non-display area NDA may include a gate driver 610, an emission control driver 620, fan-out lines FL, a first gate control line GSL1 and a second gate control line GSL2.

The fan-out lines FL may be extended from the display driver 200 to the display area DA. The fan-out lines FL may supply the data voltage received from the display driver 200 to the data lines DL.

The first gate control line GSL1 may be extended from the display driver 200 to the gate driver 610. The first gate control line GSL1 may supply the gate control signal GCS received from the display driver 200 to the gate driver 610.

The second gate control line GSL2 may be extended from the display driver 200 to the emission control driver 620. The second gate control line GSL2 may supply the emission control signal ECS received from the display driver 200 to the emission control driver 620.

The subsidiary area SBA may be extended from a side of the non-display area NDA. The subsidiary area SBA may include the display driver 200 and pads DP. The pads DP may be disposed closer to an edge of the subsidiary area SBA than the display driver 200. The pads DP may be electrically connected to the circuit board 300 through an anisotropic conductive film ACF.

The display driver 200 may include a timing controller 210 and a data driver 220.

The timing controller 210 may receive digital video data DATA and timing signals from the circuit board 300. The timing controller 210 may generate a data control signal DCS to control the operation timing of the data driver 220, may generate a gate control signal GCS to control the operation timing of the gate driver 610, and may generate an emission control signal ECS to control the operation timing of the emission control driver 620 based on the timing signals. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and may supply them to the data lines DL through the fan-out lines FL. The gate signals from the gate driver 610 may be used to select pixels PX to which a data voltage is applied, and the selected pixels PX may receive the data voltage through the data lines DL.

The power supply unit 500 may be disposed on the circuit board 300 to prevent a supply voltage to the display drivers 200 and the display panel 100. The power supply unit 500 may generate a first driving voltage to supply it to a first driving voltage line VDL, may generate an initialization voltage to supply it to an initialization voltage line VIL, and may generate a common voltage to supply it to a common electrode shared by the light-emitting elements of multiple pixels.

The gate driver 610 may be disposed on an outer side of the display area DA or on an outer side of the non-display area NDA, and the emission control driver 620 may be disposed on an opposite outer side of the display area DA or on an opposite outer side of the non-display area NDA. It should be understood, however, that the disclosure is not limited thereto. As another example, the gate driver 610 and the emission control driver 620 may be disposed on a side or an opposite side of the non-display area NDA.

The gate driver 610 may include multiple thin-film transistors for generating gate signals based on the gate control signal GCS. The emission control driver 620 may include multiple thin-film transistors for generating emission control signals based on the emission control signal ECS. For example, the transistors of the gate driver 610 and the transistors of the emission control driver 620 may be formed on the same layer as the transistors of each of the pixels PX. The gate driver 610 may supply gate signals to the gate lines GL, and the emission control driver 620 may supply emission control signals to the emission control lines EML.

FIG. 5 is a schematic diagram of a circuit of a pixel of a display device according to an embodiment of the disclosure.

Referring to FIG. 5, a pixel PX may include a light-emitting element LEL (e.g., an organic light-emitting diode) as a display element and a pixel circuit PC connected to the light-emitting element LEL. The pixel circuit PC may include first to fifth transistors T1 to T5 and first and second capacitors C1 and C2. The first transistor T1 may be a driving transistor in which a source-drain current is determined depending on a gate-source voltage. Each of the second to fifth transistors T2 to T5 may be a switching transistor that is turned on/off depending on a gate-source voltage, substantially a gate voltage. The first to fifth transistors T1 to T5 may be implemented as thin-film transistors. Depending on the types (p-type or n-type) and/or the operating conditions of the transistors, the first electrode of each of the first to fifth transistors T1 to T5 may be a source electrode or a drain electrode, while the second electrode may be the other electrode. For example, if the first electrode is the source electrode, the second electrode may be the drain electrode.

The pixel PX may be connected to a first gate line GWL transmitting a first gate signal GW, a second gate line GIL transmitting a second gate signal GI, a third gate line GRL transmitting a third gate signal GR, an emission control line EML transmitting an emission control signal EM, and a data line DL transmitting a data signal DATA. The first driving voltage line VDL may transfer a first supply voltage ELVDD to the first transistor T1. The initialization voltage line VIL may transmit an initialization voltage VINT to the light-emitting element LEL (e.g., an organic light-emitting diode). A reference voltage line VRL may transfer a reference voltage VREF to the gate electrode of the first transistor T1. Depending on the pixel structure, the above-described initialization voltage line VIL may include multiple initialization voltage lines VIL (e.g., a first initialization voltage line VIL and a second initialization voltage line VIL) that transmit initialization voltages of different levels.

The first to fifth transistors T1 to T5 may include an oxide semiconductor material. Since the oxide semiconductor has high carrier mobility and low leakage current, the voltage drop may not be large even if the driving time is long. By virtue of the oxide semiconductor, the color change of an image due to a voltage drop may not be significant even during low-frequency driving, allowing for low-frequency driving. For this reason, the first to fifth transistors T1 to T5 may include the oxide semiconductor material, so that it may be possible to implement a display device having reduced power consumption while preventing leakage current. By using the oxide semiconductor transistors, a crystallization process by excimer laser annealing (ELA) for forming a low-temperature polycrystalline silicon (LTPS) semiconductor transistor may not be required. Accordingly, the fabrication cost of the display panel 100 can be reduced, and thus a large area display device can be advantageously implemented.

An oxide semiconductor may be sensitive to light, and there may be a change in the amount of electric current or the like due to external light. To overcome this, it may be contemplated to locate a metal layer under the oxide semiconductor to absorb or reflect external light. The metal layer located under the oxide semiconductor of the first transistor T1 may work as a lower gate electrode (e.g., a counter gate electrode). In other words, the first transistor T1 may be a double-gate transistor having two gate electrodes (e.g., a gate electrode and a counter gate electrode). The gate electrode and the counter gate electrode may face each other on different layers. For example, the first transistor T1 is an n-channel oxide semiconductor transistor, and the gate electrode and the counter gate electrode of the first transistor T1 may face each other with the oxide semiconductor interposed therebetween. On the other hand, at least one of the second to fifth transistors T2 to T5 may be the above-described double-gate transistor.

The first transistor T1 may include a first gate electrode GE1 connected to a first node N1 (or gate node), a second gate electrode GE2 connected to a third node N3, a first electrode connected to a second node N2, and a second electrode connected to the third node N3. The second gate electrode GE2 of the first transistor T1 may be connected to the second electrode of the first transistor T1 and may be controlled by a voltage applied to the second electrode of the first transistor T1, so that the output saturation characteristics of the first transistor T1 can be improved. The first electrode of the first transistor T1 may be connected to the first driving voltage line VDL via the fifth transistor T5, and the second electrode may be connected to the pixel electrode of the light-emitting element LEL. The first transistor T1 may work as a driving transistor, may receive the data signal DATA according to the switching operation of the second transistor T2, and may control the magnitude of the driving current Id (for example, the amount of current) flowing to the light-emitting element LEL.

The second transistor T2 (e.g., a data write transistor) may include a first gate electrode GE1 and a second gate electrode GE2 connected to the first gate line GWL, a first electrode connected to the data line DL, and a second electrode connected to the first node N1 (or the gate electrode of the first transistor T1). The second transistor T2 may be turned on in response to the first gate signal GW transferred on the first gate line GWL to electrically connect the data line DL with the first node N1 and may transmit the data signal DATA transmitted on the data line DL to the first node N1.

The third transistor T3 (e.g., the first initialization transistor) may include a first gate electrode GE1 and a second gate electrode GE2 connected to the third gate line GRL, a first electrode connected to a reference voltage line VRL, and a second electrode connected to the first node N1 (or the gate electrode of the first transistor T1). The third transistor T3 may be turned on in response to the third gate signal GR transmitted to the third gate line GRL and may transmit the reference voltage VREF transmitted on the reference voltage line VRL to the first node N1.

The fourth transistor T4 (e.g., the second initialization transistor) may include a first gate electrode GE1 and a second gate electrode GE2 connected to the second gate line GIL, a first electrode connected to the third node N3 (or the second electrode of the first transistor T1), and a second electrode connected to the initialization voltage line VIL. The fourth transistor T4 may be turned on in response to the second gate signal GI transmitted on the second gate line GIL, and may transmit the initialization voltage VINT transmitted on the initialization voltage line VIL to the third node N3.

The fifth transistor T5 (e.g., an emission control transistor) may include the first gate electrode GE1 and the second gate electrode GE2 connected to the emission control line EML, a first electrode connected to the first driving voltage line VDL, and a second electrode connected to the second node (or the first electrode of the first transistor T1). The fifth transistor T5 may be turned on or off in response to the emission control signal EM transmitted on the emission control line EML.

A first capacitor C1 may be connected between the first node N1 and the third node N3. The first electrode of the first capacitor C1 may be connected to the gate electrode of the first transistor T1, and the second electrode may be connected to the second gate electrode GE2 and the second electrode of the first transistor T1, the first electrode of the fourth transistor T4, and the pixel electrode (e.g., anode electrode) of the light-emitting element LEL. The first capacitor C1 may be a storage capacitor and may store a threshold voltage of the first transistor T1 and a voltage corresponding to a data signal.

A second capacitor C2 may be connected between the third node N3 and the first driving voltage line VDL. The first electrode of the second capacitor C2 may be connected to the first driving voltage line VDL. The second electrode may be connected to the second gate electrode GE2 and the second electrode of the first transistor T1, the second electrode of the first capacitor C1, the first electrode of the fourth transistor T4, and the pixel electrode of the light-emitting element LEL. The capacitance of the first capacitor C1 may be greater than the capacitance of the second capacitor C2.

The light-emitting element LEL may include the pixel electrode (e.g., the anode electrode) and a counter electrode (e.g., a cathode electrode) facing the pixel electrode. The counter electrode may receive a second supply voltage ELVSS. The counter electrode may be connected to the second driving voltage line VSL transmitting the second supply voltage. The counter electrode may be a common electrode CM shared by the pixels PX.

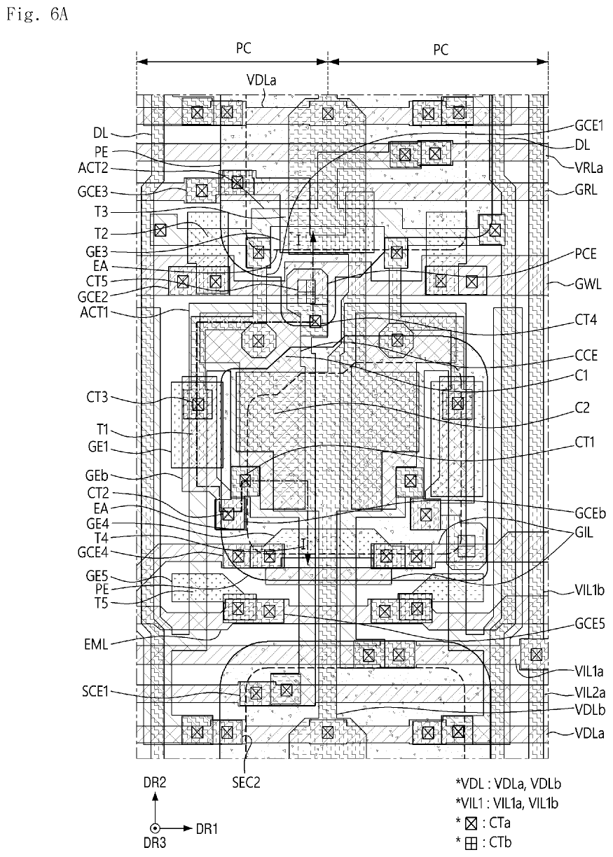

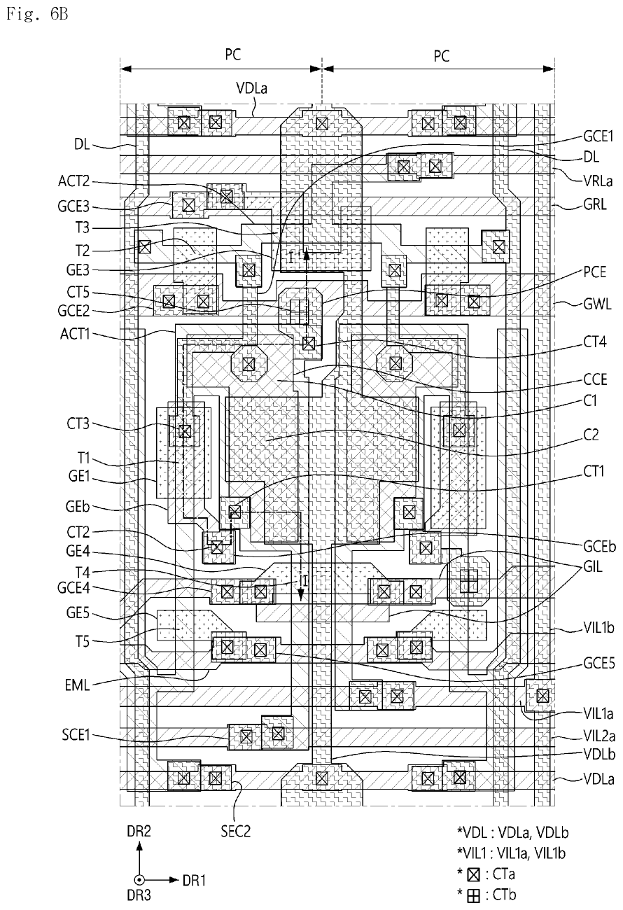

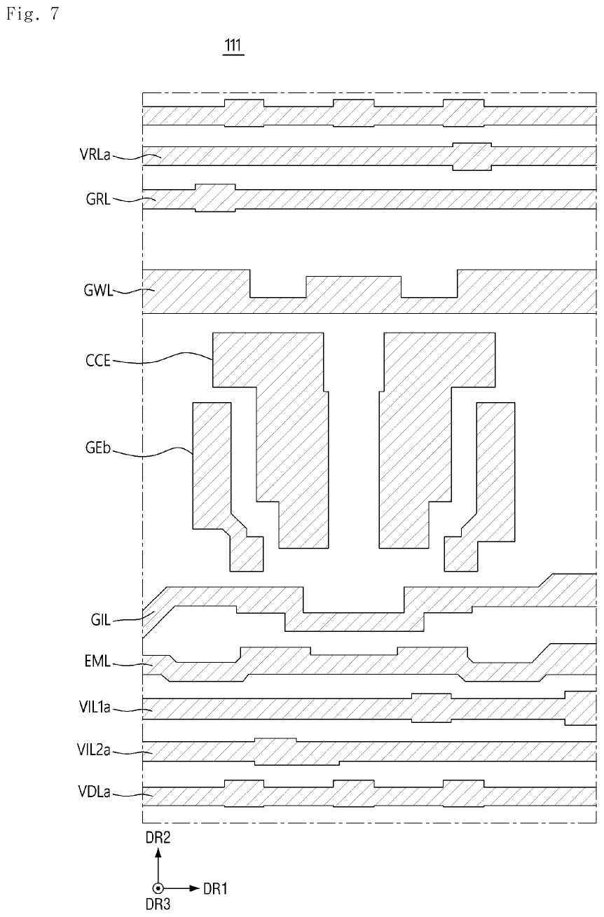

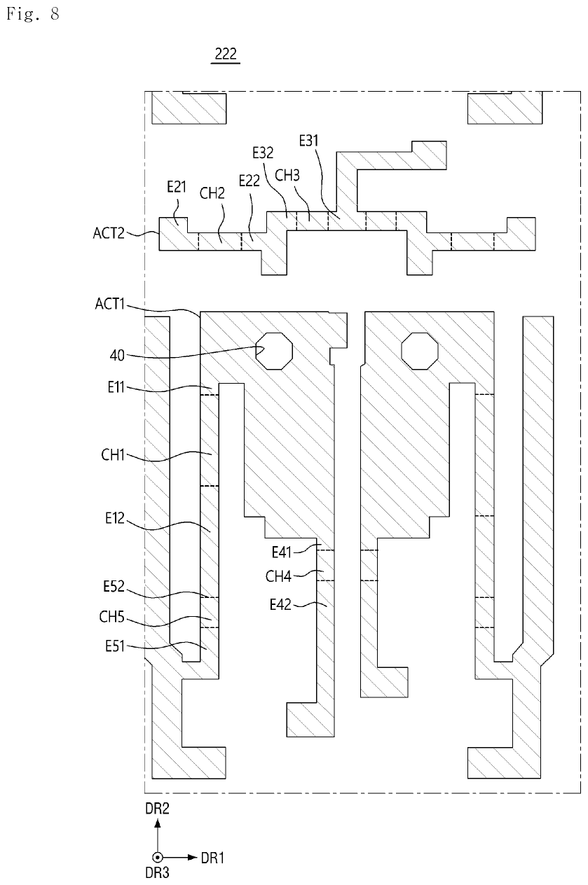

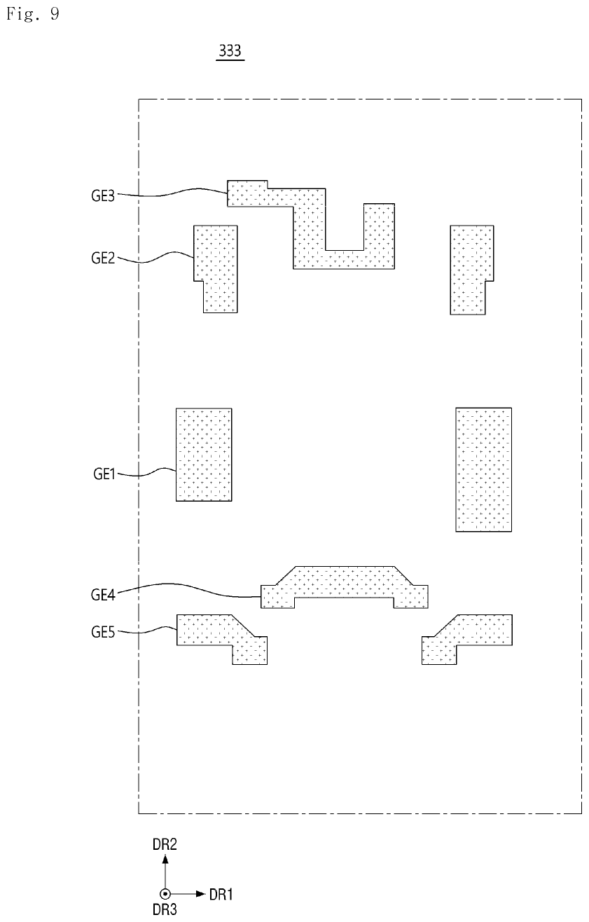

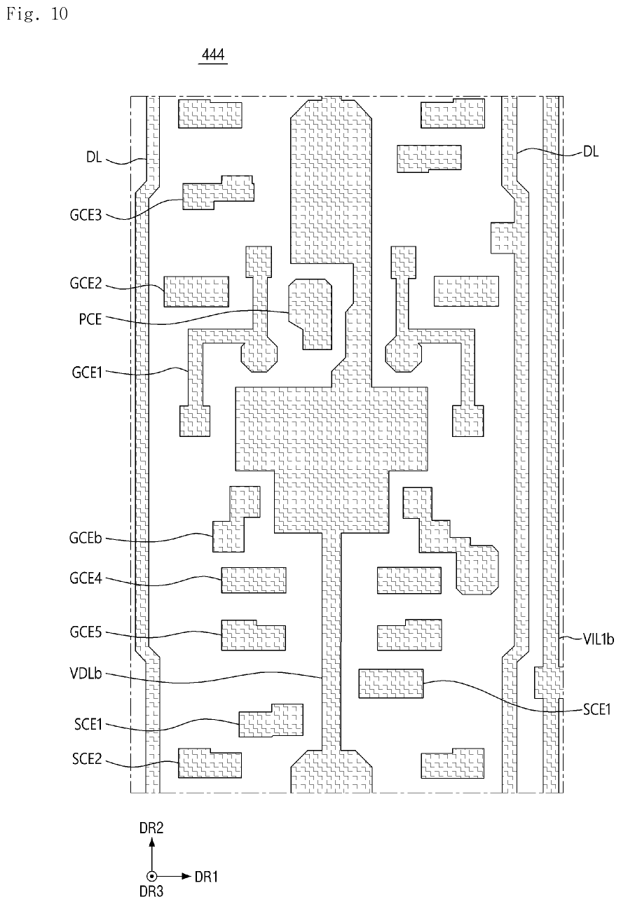

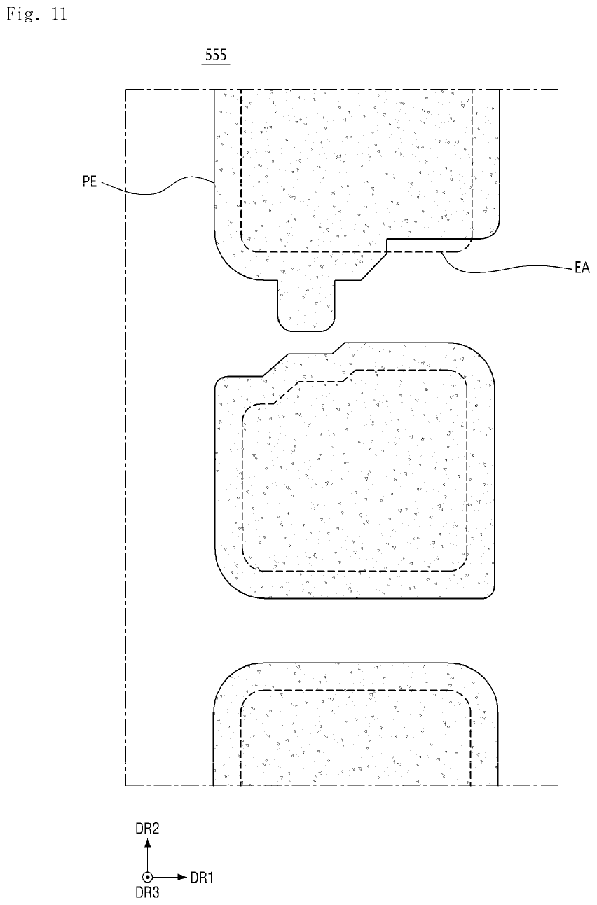

FIGS. 6A and 6B are schematic plan views of a pixel array of a display device including the pixel circuit PC of FIG. 5 according to an embodiment of the disclosure. FIG. 7 is a schematic plan view selectively showing only a first conductive layer 111 among the elements of FIG. 6A. FIG. 8 is a schematic plan view selectively showing only a second conductive layer 222 among the elements of FIG. 6A. FIG. 9 is a schematic plan view selectively showing only a third conductive layer 333 among the elements of FIG. 6A. FIG. 10 is a schematic plan view selectively showing only a fourth conductive layer 444 among the elements of FIG. 6A. FIG. 11 is a schematic plan view selectively showing only a fifth conductive layer 555 among the elements of FIG. 6A. FIG. 12 is a schematic plan view selectively showing only the second and third conductive layer 222 and 333 among the elements of FIG. 6A. FIG. 13 is a schematic plan view selectively showing only the first and second conductive layer 111 and 222 among the elements of FIG. 6A. FIG. 6B may be different from FIG. 6A at least in that only the pixel electrodes PE and the emission areas EA are not depicted.

Incidentally, as shown in FIG. 6A, contact holes may be sorted into first-type contact holes CTa and second-type contact holes CTb. The first-type contact holes CTa may connect a fourth conductive layer 444 to be described later with a conductive layer directly under it (e.g., at least one of the first to fourth conductive layers 111 to 444). The second-type contact holes may connect a sixth conductive layer (e.g., the pixel electrode PE) with a conductive layer directly under it (e.g., at least one of the first to fifth conductive layers 555).

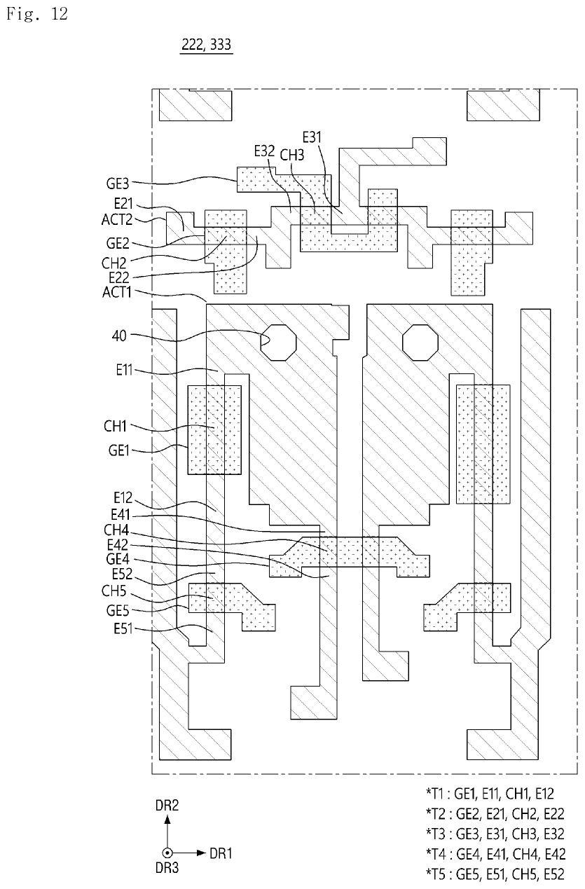

The pixel of the display device 10 according to an embodiment may include the pixel circuit PC as shown in FIGS. 6A and 6B, and the light-emitting element LEL (see FIG. 14) connected to the pixel circuit PC. FIGS. 6A and 6B show the pixel electrodes included in the light-emitting elements. A pixel array of two pixel circuits is shown in FIGS. 6A and 6B.

The pixel circuit PC may include, for example, first to fifth transistors T1 to T5, a first capacitor C1, and a second capacitor C2.

The pixel circuit PC may include, for example, the first to fifth transistors T1 to T5, the first capacitor C1 and the second capacitor C2 disposed in the region defined by being surrounded by a data line DL, the center portion of an upper reference voltage line VRLb, a lower reference voltage line VRLa, and the first lower driving voltage line VDLa.

The pixel circuit PC, for example, may be connected to the anode electrode (e.g., the pixel electrode) of the light-emitting element LEL, the data line DL, the first gate line GWL, the second gate line GIL, the third gate line GRL, the emission control line EML, the first driving voltage line VDL, the reference voltage line VRL, and the initialization voltage line (first initialization voltage line VIL1 or second initialization voltage line VIL2).

The first conductive layer 111 may be disposed on the substrate along the third direction DR3. The first conductive layer 111, as shown in FIGS. 6A, 6B and 7, may include the lower reference voltage line VRLa, the third gate line GRL, the first gate line GWL, the capacitor electrode CCE, the counter gate electrode GEb, the second gate line GIL, the emission control line EML, the first lower initialization voltage line VIL1a, the second lower initialization voltage line VIL2a, and the first lower driving voltage line VDLa.

The first gate line GWL may be extended in the first direction DR1. The first gate line GWL may be connected to the second gate electrode GE2 of the second transistor T2 through a first-type contact hole of the insulating film.

The second gate line GIL may be extended in the first direction DR1. The second gate line GIL may be connected to a fourth gate electrode GE4 of the fourth transistor T4 through a first-type contact hole of the insulating film.

The third gate line GRL may be extended in the first direction DR1. The third gate line GRL may be connected to a third gate electrode GE3 of the third transistor T3 through a first-type contact hole of the insulating film.

The emission control line EML may be extended in the first direction DR1. The emission control line EML may be connected to a fifth gate electrode GE5 of the fifth transistor T5 through a first-type contact hole of the insulating film.

The lower reference voltage line VRLa may be extended in the first direction DR1. The lower reference voltage line VRLa may be connected to the upper reference voltage line extended in the second direction through a first-type contact hole of the insulating film. The lower reference voltage lines VRLa and the upper reference voltage lines may form the reference voltage line VRL. The reference voltage line VRL including the lower reference voltage lines VRLa and the upper reference voltage lines may have a mesh shape.

The first lower initialization voltage line VIL1a may be extended in the first direction DR1. The first lower initialization voltage line VILa may be connected to a pixel of a color among three pixels providing lights of different wavelengths. For example, the first lower initialization voltage line VIL1a may be connected to the fourth transistor T4 of a green pixel (e.g., a second pixel including a second pixel circuit PC2) providing light corresponding to the green wavelength. The first lower initialization voltage line VIL1a may be connected to the first upper initialization voltage line extended in the second direction through a first-type contact hole of the insulating film. The first lower initialization voltage lines VIL1a and the first upper initialization voltage lines may form the first initialization voltage line VILL. The first initialization voltage line VIL1 including the first lower initialization voltage lines and the first upper initialization voltage lines may have a mesh shape.

The second lower initialization voltage line VIL2a may be extended in the first direction DR1. The second lower initialization voltage line VIL2a may be connected to pixels of two or more colors among the three pixels described above. For example, the second lower initialization voltage line VIL2a may be connected in common to two pixels other than the pixel connected to the first lower initialization voltage line among the three pixels described above. For example, the second lower initialization voltage line VIL2a may be connected to a fourth transistor T4 of a red pixel that provides light of a red wavelength (e.g., a first pixel including a first pixel circuit PC1), and a fourth transistor T4 of a blue pixel that provides light of a blue wavelength (e.g., a third pixel including a third pixel circuit). The second lower initialization voltage line VIL2a may be connected to a second upper initialization voltage line extended in the second direction through a first-type contact hole of the insulating film. The second lower initialization voltage lines VIL2a and the second upper initialization voltage lines may form the second initialization voltage line VIL2. The second initialization voltage line VIL2 including the second lower initialization voltage lines and the second upper initialization voltage lines may have a mesh shape.

The first lower driving voltage line VDLa may be extended in the first direction DR1. The first lower driving voltage line VDLa may be connected to the first upper driving voltage line VDLb extended in the second direction through a first-type contact hole of the insulating film. Multiple first lower driving voltage lines VDLa and multiple first upper driving voltage lines VDLb may form the first driving voltage line VDL. The first driving voltage line VDL including the first lower driving voltage lines VDLa and the first upper driving voltage lines VDLb may have a mesh shape.

The capacitor electrode CCE may include the first electrode of the first capacitor. The capacitor electrode CCE may be connected to a first gate connection electrode through a first-type contact hole of the insulating film and a hole of the first active layer ACT1.

The counter gate electrode GEb may be disposed adjacent to the capacitor electrode CCE. The counter gate electrode GEb may be the lower gate electrode of the first transistor T1. The counter gate electrode GEb may be connected to the first active layer ACT1 through a counter gate connection electrode GCEb. For example, the counter gate electrode GEb may be connected to the counter gate connection electrode GCEb through a first-type contact hole in the insulating film, and the counter gate connection electrode GCEb may be connected to the first active layer ACT1 through a first-type contact hole of the insulating film.

The second conductive layer 222 may be disposed on the first conductive layer 111 in the third direction DR3. An insulating film may be disposed between the first conductive layer 111 and the second conductive layer 222. As shown in FIGS. 6A, 6B, 8 and 12, the second conductive layer 222 may include the first active layer ACT1 and the second active layer ACT2 physically separated from each other.

The first active layer ACT1 may form the first transistor T1, the fourth transistor T4 and the fifth transistor T5 along with the first gate electrode GE1, the fourth gate electrode GE4 and the fifth gate electrode GE5, respectively. For example, as shown in FIGS. 8 and 12, the first active layer ACT1 may include a first electrode E11 of the first transistor T1, a second electrode E12 of the first transistor T1, a first channel region CH1 of the first transistor T1, a first electrode E41 of the fourth transistor T4, a second electrode E42 of the fourth transistor T4, a fourth channel region CH4 of the fourth transistor T4, a first electrode E51 of the fifth transistor T5, a second electrode E52 of the fifth transistor T5, and a fifth channel region CH5 of the fifth transistor T5. Each of the first electrodes E11, E41 and E51 of the first, fourth and fifth transistors T1, T4 and T5 may be one of a source electrode and a drain electrode of that transistor. Each of the second electrodes E12, E42 and E52 of the first, fourth and fifth transistors T1, T4 and T5 may be the other of the source electrode and the drain electrode of that transistor.

A part of the first active layer ACT1 may correspond to the second electrode of the first capacitor C1 and the first electrode C1 of the second capacitor. For example, the first capacitor C1 may be formed between the first active layer ACT1 and the capacitor electrode CCE overlapping each other in the third direction. Incidentally, the second capacitor C2 may be formed between the first active layer ACT1 and the first upper driving voltage line VDLb overlapping each other in the third direction, which will be described later.

The first active layer ACT1 may have a hole 40 penetrating through it in the third direction. For example, the hole 40 penetrating through the first active layer ACT1 may be formed in a part of the first active layer ACT1 that corresponds to the first electrode E11. The first gate connection electrode GCE1 and the capacitor electrode CCE may be connected with each other through the hole 40.

As shown in FIGS. 6A and 6B, the first active layer ACT1 may be connected to the second lower initialization voltage line VIL2a through a first source connection electrode. For example, the first active layer ACT1 may be connected to the first source connection electrode through a contact hole (e.g., a first-type contact hole) of the insulating film, and the first source connection electrode may be connected to the second lower initialization voltage line VIL2a through a contact hole (e.g., a first-type contact hole) of the insulating film.

As shown in FIGS. 6A and 6B, the first active layer ACT1 of another pixel circuit (e.g., the right pixel circuit) may be connected to the first lower initialization voltage line VIL1a through the first source connection electrode. For example, the first active layer ACT1 may be connected to the first source connection electrode through a contact hole (e.g., a first-type contact hole) of the insulating film, and the first source connection electrode may be connected to the first lower initialization voltage line VIL1a through a contact hole (e.g., a first-type contact hole) of the insulating film.

As shown in FIGS. 6A and 6B, the first active layer ACT1 may be connected to the first lower initialization voltage line VDLa through a second source connection electrode. For example, the first active layer ACT1 may be connected to the second source connection electrode through a contact hole (e.g., a first-type contact hole) of the insulating film, and the second source connection electrode may be connected to the first lower driving voltage line VDLa through a contact hole (e.g., a first-type contact hole) of the insulating film.

As shown in FIGS. 6A and 6B, a part of the first active layer ACT1 may be extended along the longitudinal direction of the data line DL such that it overlaps the data line DL, and may be connected to the first lower driving voltage line VDLa. Since the data line DL is adjacent to the first capacitor C1 (e.g., the capacitor electrode CCE and the first active layer ACT1), it may be coupled with the voltage of the first capacitor C1 (e.g., the voltage of the capacitor electrode CCE and the first active layer ACT1), so that the voltage of the data line DL (e.g., the data voltage) may be changed. In other words, the data voltage of the data line DL may become unstable. The first active layer ACT1 may overlap the data line DL in the third direction DR3 in order to shield the data line DL and receive a constant voltage (e.g., the first driving voltage from the first lower driving voltage line VDLa), to suppress the coupling between the voltage of the data line DL and the voltage of the first capacitor C1. In this manner, it may be possible to stabilize the data voltage of the data line DL.

The first active layer ACT1 may include a material such as polycrystalline silicon, single crystal silicon, low-temperature polycrystalline silicon, and/or amorphous silicon and an oxide semiconductor. In case that the first active layer ACT1 includes an oxide semiconductor material, the first active layer ACT1 may include indium-gallium-zinc-oxide (IGZO) or indium-gallium-zinc-tin oxide (IGZTO). In case that the first active layer ACT1 includes polycrystalline silicon or an oxide semiconductor material, the source region and the drain region of the first active layer ACT1 may be doped with ions and thus may be conductive regions.

The second active layer ACT2 may form the second and third transistors T2 and T3 together with the second and third gate electrodes GE2 and GE3 to be described later. For example, as shown in FIGS. 8 and 12, the second active layer ACT2 may include a first electrode E21 of the second transistor T2, a second electrode E22 of the second transistor T2, a second channel region CH2 of the second transistor T2, a first electrode E31 of the third transistor T3, a second electrode E32 of the third transistor T3, and a third channel region CH3 of the third transistor T3. The first electrode of each of the second and third transistors T2 and T3 may be one of the source electrode and the drain electrode of the respective transistors, and the second electrode of each of the second and third transistors T2 and T3 may be the other one of the source electrode and the drain electrode of the respective transistors.

The second active layer ACT2 may include a material such as polycrystalline silicon, single crystal silicon, low-temperature polycrystalline silicon, and/or amorphous silicon and an oxide semiconductor. In case that the second active layer ACT2 includes an oxide semiconductor material, the second active layer ACT2 may include indium-gallium-zinc-oxide (IGZO) or indium-gallium-zinc-tin oxide (IGZTO). In case that the second active layer ACT2 includes polycrystalline silicon or an oxide semiconductor material, the source region and the drain region of the second active layer ACT2 may be doped with ions and thus may be conductive regions.

It should be noted that some areas of the first active layer ACT1 may contain nitrogen having a different size from the other regions of the first active layer ACT1. For example, a part of the first active layer ACT1 that is included in the first transistor T1 may contain a different amount of nitrogen than the other parts of the first active layer ACT1 that are included in the other transistors. For example, the nitrogen content per unit area of the active layer of the fourth transistor T4 may be greater than the nitrogen content per unit area of the active layer of the first transistor T1. In the example shown in FIG. 13, a first area A1 of the first active layer ACT1 that is overlapped by the counter gate electrode GEb of the first transistor T1 may be defined as the active layer of the first transistor T1, and the other area of the first active layer ACT1 than the first area A1 may be defined as a second area. The nitrogen content of the second area may be greater than the nitrogen content of the first area. The nitrogen content of the first area A1 may be zero, and the nitrogen content of the second area may be greater than zero.

In the example shown in FIG. 13, the first area A1 may include, for example, the first electrode E11 of the first transistor T1 (e.g., the drain region of the first transistor T1), the second electrode E12 of the first transistor T1 (e.g., the drain region of the first transistor T1), and the first channel region CH1 of the first transistor T1. The second area may include, for example, the first electrode E41 of the fourth transistor T4 (e.g., the drain region of the fourth transistor T4), the second electrode E42 of the fourth transistor T4 (e.g., a source region of the fourth transistor T4), the fourth channel region CH4 of the fourth transistor T4, the first electrode E51 of the fifth transistor T5 (e.g., the drain region of the fifth transistor T5), the second electrode E52 of the fifth transistor T5 (e.g., the source region of the fifth transistor T5), and the fifth channel region CH5 of the fifth transistor T5.

It should be noted that the range of the first area A1 of the first active layer ACT1 shown in FIG. 13 is merely illustrative. For example, as shown in FIG. 12, the first area of the first active layer ACT1 may be defined as an area of the first active layer ACT1 that is overlapped by the first gate electrode GE1 of the first transistor T1. The first area may substantially be identical to the first channel region CH1 of the first transistor T1. The second area of the first active layer ACT1 may be the other area of the first active layer ACT1 than the first channel region CH1.

As another example, the first area of the first active layer ACT1 may include at least a part of the first active layer ACT1 that corresponds to the first electrode E11 of the first transistor T1, at least a part of the first active layer ACT1 that corresponds to the second electrode E12 of the first transistor T1, and the first channel area CH1. The second area of the first active layer ACT1 may be the other area of the first active layer ACT1 than the first area.

As another example, the first area of the first active layer ACT1 may include a part of the first active layer ACT1 that corresponds to the first electrode E11 of the first transistor T1, a part that is formed integrally with the first electrode E11 and corresponds to the first electrode E41 of the fourth transistor T4, a part of the first active layer ACT1 that corresponds to the second electrode E12 of the first transistor T1, a part that is formed integrally with the second electrode E52 and corresponds to the second electrode E52 of the fifth transistor T5, and the first channel region CH1. In other words, in the plan views of FIGS. 8 and 12, the first area may include all parts of the first active layer ACT1 disposed on the path between a side of the first gate electrode GE1 and the fourth gate electrode GE4, all parts of the first active layer ACT1 disposed on the path between the opposite side of the first gate electrode GE1 and the fifth gate electrode GE5, and the first channel region CH1. The second area of the first active layer ACT1 may be the other area of the first active layer ACT1 than the first area.

As shown in FIG. 12, as an example of the second area, the second area of the first active layer ACT1 may be defined as an area of the first active layer ACT1 that is overlapped by the fourth gate electrode GE4 of the fourth transistor T4. The second area may substantially be identical to the fourth channel region CH4 of the fourth transistor T4. The first area of the first active layer ACT1 may be the other area of the first active layer ACT1 than the fourth channel region CH4.

As another example, the second area of the first active layer ACT1 may include at least a part of the first active layer ACT1 that corresponds to the first electrode E41 of the fourth transistor T4, at least a part of the first active layer ACT1 that corresponds to the second electrode E42 of the fourth transistor T4, and the first channel area CH1. The first area of the first active layer ACT1 may be the other area of the first active layer ACT1 than the second area.

As another example, the second area of the first active layer ACT1 may include a part of the first active layer ACT1 that corresponds to the first electrode E41 of the fourth transistor T4, a part that is formed integrally with the first electrode E41 and corresponds to the first electrode E11 of the first transistor T1, a part of the first active layer ACT1 that corresponds to the second electrode E42 of the fourth transistor T4, and the fourth channel region CH4. In other words, in the plan views of FIGS. 8 and 12, the second area may include all parts of the first active layer ACT1 disposed on the path between a side of the fourth gate electrode GE4 and the first gate electrode GE1, all parts of the first active layer ACT1 disposed on the opposite side of the fourth gate electrode GE4, and the fourth channel region CH4. The first area of the first active layer ACT1 may be the other area of the first active layer ACT1 than the second area.

The second active layer ACT2 may contain nitrogen like the second area of the first active layer ACT1 described above. In other words, the nitrogen content per unit area of the second active layer ACT2 may be greater than the nitrogen content per unit area of the first area of the first active layer ACT1. In other embodiments, the second active layer ACT2 may contain no nitrogen like the first area of the first active layer ACT1 described above. In other words, the nitrogen content per unit area of the second area of the first active layer ACT1 may be greater than the nitrogen content per unit area of the second active layer ACT2.

As described above, since the fourth transistor T4, which is a switching transistor, includes the active layer containing a larger amount of nitrogen than the first transistor T1, which is the driving transistor, the threshold voltage of the fourth transistor T4 may be higher than the threshold voltage of the transistor T1. In other words, the threshold voltage of the fourth transistor T4 may be shifted in a positive direction. Accordingly, leakage current of the fourth transistor T4 can be further suppressed. On the other hand, since the active layer of the first transistor T1 serving as the driving transistor contains substantially no nitrogen, the current driving capability of the first transistor T1 may not deteriorate.

Incidentally, the active layer of at least one of the switching transistors (e.g., the transistors T2 to T5) may contain a larger amount of nitrogen per unit area than the active layer of the first transistor T1 serving as the driving transistor.

The third conductive layer 333 may be disposed on the second conductive layer 222 in the third direction DR3. An insulating film may be disposed between the second conductive layer 222 and the third conductive layer 333. As shown in FIGS. 6A, 6B, 9 and 12, the third conductive layer 333 may include the third gate electrode GE3, the second gate electrode GE2, the first gate electrode GE1, the fourth gate electrode GE4 and the fifth gate electrode GE5.

The first gate electrode GE1 may be a gate electrode (e.g., an upper gate electrode) of the first transistor T1. As shown in FIG. 12, the first gate electrode GE1 may partially overlap the first active layer ACT1. As shown in FIGS. 9 and 12, the first channel region CH1 of the first transistor T1 may be formed where the first gate electrode GE1 overlaps the first active layer ACT1. The first electrode E11 and the second electrode E12 of the first transistor T1 may be formed in the areas of the first active layer ACT1 on both sides of the first channel region CH1, respectively.

The first gate electrode GE1 may overlap the counter gate electrode GEb in the third direction DR3 as shown in FIGS. 6A and 6B. The first channel region CH1 of the first active layer ACT1 described above may be disposed between the first gate electrode GE1 and the counter gate electrode GEb.

The second gate electrode GE2 may be a gate electrode of the second transistor T2. As shown in FIG. 12, the second gate electrode GE2 may overlap a part of the second active layer ACT2 in the third direction DR3. As shown in FIGS. 9 and 12, the second channel region CH2 of the second transistor T2 may be formed where the second gate electrode GE2 overlaps the second active layer ACT2. The first electrode E21 and the second electrode E22 of the second transistor T2 may be formed in the areas of the second active layer ACT2 on both sides of the second channel region CH2, respectively.

The third gate electrode GE3 may be a gate electrode of the third transistor T3. As shown in FIG. 12, the third gate electrode GE3 may overlap a part of the second active layer ACT2 in the third direction DR3. As shown in FIGS. 9 and 12, the third channel region CH3 of the third transistor T3 may be formed where the third gate electrode GE3 overlaps the second active layer ACT2. The first electrode E31 and the second electrode E32 of the third transistor T3 may be formed in the areas of the second active layer ACT2 on both sides of the third channel region CH3, respectively.

The fourth gate electrode GE4 may be a gate electrode of the fourth transistor T4. As shown in FIG. 12, the fourth gate electrode GE4 may overlap a part of the first active layer ACT1 in the third direction DR3. As shown in FIGS. 9 and 12, the fourth channel region CH4 of the fourth transistor T4 may be formed where the fourth gate electrode GE4 overlaps the first active layer ACT1. The first electrode E41 and the second electrode E42 of the fourth transistor T4 may be formed in the areas of the first active layer ACT1 on both sides of the fourth channel region CH4, respectively.

The fifth gate electrode GE5 may be a gate electrode of the fifth transistor T5. As shown in FIG. 12, the fifth gate electrode GE5 may overlap a part of the first active layer ACT1 in the third direction DR3. As shown in FIGS. 9 and 12, the fifth channel region CH5 of the fifth transistor T5 may be formed where the fifth gate electrode GE5 overlaps the first active layer ACT1. The first electrode E51 and the second electrode E52 of the fifth transistor T5 may be formed in the areas of the first active layer ACT1 on both sides of the fifth channel region CH1, respectively.

The fourth conductive layer 444 may be disposed on the third conductive layer 333 in the third direction DR3. An insulating film may be disposed between the third conductive layer 333 and the fourth conductive layer 444. As shown in FIGS. 6A, 6B and 10, the fourth conductive layer 444 may include a data line DL, a first upper driving voltage line VDLb, an upper reference voltage line VRLb, a third gate connection electrode GCE3, a second gate connection electrode GCE2, a first gate connection electrode GCE1, a pixel connection electrode PCE, a counter gate connection electrode GCEb, a fourth gate connection electrode GCE4, a source connection electrode SCE, and a fifth gate connection electrode GCE5.

The data line DL may be extended in the second direction DR2. As shown in FIG. 6A, the data line DL may be connected to the first electrode E21 of the second transistor T2 through a contact hole (e.g., a first-type contact hole CTa) of the insulating film. For example, the data line DL may be connected to a part of the second active layer ACT2 that corresponds to the first electrode E21 of the second transistor T2 through the contact hole of the insulating film described above.

As shown in FIGS. 6A and 6B, the data line DL may overlap the first active layer ACT1 in the third direction DR3.

The first upper driving voltage line VDLb may be extended in the second direction DR2. As shown in FIGS. 6A and 6B, the first upper driving voltage line VDLb may be connected to the first lower driving voltage line VDLa through a contact hole of the insulating film (e.g., a first-type contact hole CTa).

As shown in FIGS. 6A and 6B, the first upper driving voltage line VDLb may overlap the first active layer ACT1 in the third direction DR3. A second capacitor C2 may be formed where the first upper driving voltage line VDLb and the first active layer ACT1 overlap each other. For example, the second capacitor C2 may be disposed between a part of the first active layer ACT1 that corresponds to the first electrode E11 of the first transistor T1 and the first upper driving voltage line VDLb overlapping it in the third direction DR3. The first upper driving voltage line VDLb and the first active layer ACT1 may be the first electrode and the second electrode of the second capacitor C2, respectively.

The first gate connection electrode GCE1 may be extended in the second direction DR2. The first gate connection electrode GCE1 may have a curved shape around the second gate connection electrode GCE2 and may be extended in the second direction DR2. As shown in FIGS. 6A and 6B, the first gate connection electrode GCE1 may be connected to the second electrode E21 of the second transistor T2 through a contact hole (e.g., a first-type contact hole CTa) of the insulating film. For example, the first gate connection electrode GCE1 may be connected to a part of the second active layer ACT2 that corresponds to the second electrode E22 of the second transistor T2 through the first-type contact hole CTa described above. The first gate connection electrode GCE1 may be connected to a capacitor electrode CCE through a contact hole (e.g., a first-type contact hole) of the insulating film and a hole 40 of the first active layer ACT1. The first gate connection electrode GCE1 may be connected to the first gate electrode GE1 through a contact hole (e.g., a first-type contact hole) of the insulating film.

As shown in FIGS. 6A and 6B, the second gate connection electrode GCE2 may be connected to the second gate electrode GE2 through a contact hole (e.g., a first-type contact hole CTa) of the insulating film. The second gate connection electrode GCE2 may be connected to the first gate electrode GWL through a contact hole (e.g., a first-type contact hole CTa) of the insulating film.

As shown in FIGS. 6A and 6B, the third gate connection electrode GCE3 may be connected to the third gate electrode GE3 through a contact hole (e.g., a first-type contact hole CTa) of the insulating film. The third gate connection electrode GCE3 may be connected to the third gate electrode GRL through a contact hole (e.g., a first-type contact hole) of the insulating film.

As shown in FIGS. 6A and 6B, the fourth gate connection electrode GCE4 may be connected to the fourth gate electrode GE4 through a contact hole (e.g., a first-type contact hole CTa) of the insulating film. The fourth gate connection electrode GCE4 may be connected to the second gate electrode GIL through a contact hole (e.g., a first-type contact hole) of the insulating film.

As shown in FIGS. 6A and 6B, the fifth gate connection electrode GCE5 may be connected to the fifth gate electrode GE5 through a contact hole (e.g., a first-type contact hole CTa) of the insulating film. The fifth gate connection electrode GCE5 may be connected to an emission control line EML through a contact hole (e.g., a first-type contact hole CTa) of the insulating film.

As shown in FIGS. 6A and 6B, the counter gate connection electrode GCEb may be connected to the counter gate electrode GEb through a contact hole (e.g., a first-type contact hole CTa) of the insulating film. The counter gate connection electrode GCEb may be connected to the first active layer ACT1 through a contact hole (e.g., a first-type contact hole CTa) of the insulating film. For example, the counter gate electrode GCEb may be connected to a part of the first active layer ACT1 that corresponds to the first electrode E11 of the first transistor T1 through the first-type contact hole CTa.

As shown in FIGS. 6A and 6B, the first source connection electrode SCE1 may be connected to the first active layer ACT1 through a contact hole (e.g., a first-type contact hole CTa) of the insulating film. For example, the first source connection electrode SCE1 may be connected to a part of the first active layer ACT1 that corresponds to the second electrode E42 of the fourth transistor T4 through the first-type contact hole CTa described above. The first source connection electrode SCE1 may be connected to the second lower initialization voltage line VIL2a through a contact hole (e.g., a first-type contact hole) of the insulating film. On the other hand, a first source connection electrode SCE1 of another pixel circuit may be connected to the first lower initialization voltage line VIL1a through a contact hole (e.g., a first-type contact hole) of the insulating film.

As shown in FIGS. 6A and 6B, the second source connection electrode SCE2 may be connected to the first active ACT1 through a contact hole (e.g., a first-type contact hole CTa) of the insulating film. For example, the second source connection electrode SCE2 may be connected to a part of the first active layer ACT1 that corresponds to the first electrode E51 of the fifth transistor T5 through the first-type contact hole CTa described above. The second source connection electrode SCE2 may be connected to the first lower driving voltage line VDLa through a contact hole (e.g., a first-type contact hole) of the insulating film.

As shown in FIGS. 6A and 6B, the pixel connection electrode PCE may be connected to the first active ACT1 through a contact hole (e.g., a first-type contact hole CTa) of the insulating film. For example, the pixel connection electrode PCE may be connected to a part of the first active layer ACT1 that corresponds to the first electrode E11 of the first transistor T1 through the first-type contact hole CTa.

Incidentally, the fourth conductive layer 444 may further include, for example, the upper reference voltage line, the second upper initialization voltage line and the second driving voltage line described above. Each of the upper reference voltage line, the second upper initialization voltage line and the second driving voltage line may be extended in the second direction.

The fifth conductive layer 555 may be disposed on the fourth conductive layer 444 in the third direction DR3. An insulating film may be disposed between the fourth conductive layer 444 and the fifth conductive layer 555. The fifth conductive layer 555 may include a pixel electrode as shown in FIGS. 6A and 11. As shown in FIG. 6A, the pixel electrode may be connected to the pixel connection electrode PCE through a contact hole (e.g., a second-type contact hole) of the insulating film. Among the pixel electrodes shown in FIG. 11, a pixel electrode disposed at the top may be connected to a pixel connection electrode PCE of the left pixel circuit. Among the pixel electrodes shown in FIG. 11, a pixel electrode disposed in the middle may be connected to a pixel connection electrode PCE of the right pixel circuit.

A part of each of the pixel electrodes may be exposed by a bank to be described later. For example, the bank may have multiple openings EA (hereinafter referred to as emission areas) exposing a part of each of the pixel electrodes. The emission areas EA may correspond to the respective pixel electrodes excluding the edges.

FIG. 14 is a schematic cross-sectional view taken along line I-I′ of FIG. 6A.

As shown in FIG. 14, the display device 10 may include the substrate SUB, the barrier film BR, the thin-film transistor layer TFTL, the emission layer EMTL, and the encapsulation layer ENC. The barrier film BR, the thin-film transistor layer TFTL, the emission layer EMTL and the encapsulation layer ENC may be sequentially disposed on the substrate SUB in the third direction DR3. The thin-film transistor layer TFTL may include the above-described pixel circuit PC.

The substrate SUB may be a rigid substrate or a flexible substrate that can be bent, folded, rolled, and so on. The substrate SUB may be made of an insulating material such as glass, and/or quartz and a polymer resin. Examples of the polymer material may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CTA), cellulose acetate propionate (CAP), or a combination thereof. In other embodiments, the first substrate SUB may include a metal material.

As shown in FIG. 14, the barrier film BR may be disposed on the substrate SUB. The barrier film BR may be a film for protecting the thin-film transistors T1 to T8 of the thin-film transistor layer TFTL and an emissive layer 172 of the emission layer EMTL from the moisture permeating through the substrate SUB that is vulnerable to moisture. The barrier film BR may be made up of multiple inorganic films stacked on one another alternately. For example, the buffer film BR may be made up of multiple layers in which one or more inorganic layers of a silicon nitride layer, a silicon oxynitride layer, a silicon oxide layer, a titanium oxide layer and an aluminum oxide layer are alternately stacked on one another.

The first conductive layer 111 may be disposed on the barrier film BR. For example, as shown in FIGS. 6A, 7 and 14, a lower reference voltage line VRLa, a third gate line GRL, a first gate line GWL, a capacitor electrode CCE, a counter gate electrode GEb, a second gate line GIL, an emission control line EML, a second lower initialization voltage line VIL2a, a first lower initialization voltage line VIL2a, and a first lower driving voltage line VDLa. In the example shown in FIG. 14, the capacitor electrode CCE, the counter gate electrode GEb and the first gate line GWL are disposed on the barrier film BR.

As shown in FIG. 14, the buffer film BF may be disposed on the first conductive layer 111. The buffer film BF may be disposed on the entire surface of the substrate SUB including the first conductive layer 111. The barrier film BR may be a film for protecting the thin-film transistors of the thin-film transistor layer TFTL and the emissive layer EL of the emission layer EMTL from the moisture permeating through the substrate SUB that is vulnerable to moisture. The buffer film BF may be made up of multiple inorganic films stacked on one another alternately. For example, the buffer layer BF may be made up of multiple layers in which one or more inorganic layers of a silicon nitride layer, a silicon oxynitride layer, a silicon oxide layer, a titanium oxide layer and an aluminum oxide layer are alternately stacked on one another.

The second conductive layer 222 may be disposed on the buffer film BF. For example, as shown in FIGS. 6A, 8 and 14, the first active layer ACT1 and the second active layer ACT2 may be disposed on the buffer film BF. In the example shown in FIG. 14, the first active ACT1 including the first electrode E41 of the fourth transistor T4, the fourth channel region CH4 of the fourth transistor T4, the second electrode E42 of the fourth transistor T4, the first electrode E11 of the first transistor T1, the first channel region CH1 of the first transistor T1, and the second electrode E12 of the first transistor T1 may be disposed on the film BF. As shown in FIG. 14, the first active layer ACT1 may be disposed on the buffer film BF such that the first channel region CH1 of the first active layer ACT1 overlaps the first counter gate electrode GEb in the third direction DR3 and the first electrode E41 of the first active layer ACT1 overlaps the capacitor electrode CCE. In the example shown in FIG. 14, the first capacitor C1 is formed between the first active layer ACT1 and the capacitor electrode CCE.

The first active layer ACT1 may be, for example, oxide semiconductor. For example, the first active layer ACT1 may be an oxide semiconductor that includes indium-gallium-zinc-oxide (IGZO) or indium-gallium-zinc-tin oxide (IGZTO).

Incidentally, as shown in FIG. 14, the second area of the first active layer ACT1 may include all parts of the first active layer ACT1 that correspond to the second electrode E42 of the fourth transistor T4, the fourth channel region CH4, and a part of the first electrode E41 of the fourth transistor T4. The part of the first electrode E41 may include, for example, a first contact hole CT1, a part of the capacitor electrode CCE, and a part of the first active layer ACT1 overlapping a part of the first upper driving voltage line VDLb. As shown in FIG. 14, the first area of the first active layer ACT1 may be the other area of the first active layer ACT1 than the second area. The nitrogen content per unit area of the second area may be greater than the nitrogen content per unit area of the first area.

As shown in FIG. 14, a gate insulator GTI may be disposed on the second conductive layer 222. For example, the gate insulator GTI may be disposed on the first active layer ACT1 and the second active layer ACT2. The gate insulator may overlap the channel regions of the first active layer ACT1 and the channel regions of the second active layer ACT2. In the example shown in FIG. 14, a second gate insulator GTI is disposed on the first active layer ACT1 such that it is in line with the fourth channel region CH4 and the first channel region CH1 of the first active layer ACT1. It should be noted that the gate insulator GTI may have the same shape as each of the gate electrodes GE1 to GE5. The gate insulator GTI may include at least one of tetraethoxysilane (TetaraEthylOrthoSilicate, TEOS), silicon nitride (SiNx), and silicon oxide (SiO₂). For example, the first gate insulator GTI1 may have a double layer structure in which a silicon nitride film having the thickness of 40 nm and a tetraethoxysilane layer having the thickness of 80 nm are stacked on one another.

The third conductive layer 333 may be disposed on the gate insulator GTI. For example, as shown in FIGS. 6A, 9 and 14, the third gate electrode GE3, the second gate electrode GE2, the first gate electrode GE1, the fourth gate electrode GE4 or the fifth gate electrode GE5 may be disposed on each gate insulator GTI. In the example shown in FIG. 14, the fourth gate electrode GE4, the first gate electrode GE1 and the third gate electrode GE3 are disposed on each gate insulator GTI.

As shown in FIG. 14, an interlayer dielectric film ITL may be disposed on the third conductive layer 333. The interlayer dielectric film ITL may be disposed on the entire surface of the substrate SUB including the third conductive layer 333. The interlayer dielectric film ITL may have a greater thickness than the gate insulator GTI. Herein, the thickness may refer to the size in the third direction DR3. The interlayer dielectric film ITL may include an inorganic layer, for example, a silicon nitride layer, a silicon oxynitride layer, a silicon oxide layer, a titanium oxide layer, and/or an aluminum oxide layer. The interlayer dielectric film ITL may include a number of inorganic films.

The fourth conductive layer 444 may be disposed on the interlayer dielectric film ITL. For example, as shown in FIGS. 6A, 10 and 14, a data line DL, a first upper driving voltage line VDLb, an upper reference voltage line VRLb, a third gate connection electrode GCE3, a second gate connection electrode GCE2, a first gate connection electrode GCE1, a pixel connection electrode PCE, a counter gate connection electrode GCEb, a fourth gate connection electrode GCE4, a source connection electrode SCE, and a fifth gate connection electrode GCE5 may be disposed on the interlayer dielectric film ITL. In the example shown in FIG. 14, the first upper driving voltage line VDLb, the counter gate connection electrode GCEb, the first gate connection electrode GCE1 and the pixel connection electrode PCE are disposed on the interlayer dielectric film ITL. The counter gate connection electrode GCEb may be connected to the first electrode E41 of the fourth transistor T4 through the first contact hole CT1 penetrating the interlayer dielectric film ITL. In other words, the counter gate connection electrode GCEb may be connected to a part of the second area of the first active ACT1 that corresponds to the first electrode E41 of the fourth transistor T4. The counter gate connection electrode GCEb may be connected to the counter gate electrode GEb through a second contact hole CT2 penetrating the interlayer dielectric film ITL and the buffer film BF. The first gate connection electrode GCE1 may be connected to the first gate electrode GE1 through a third contact hole CT3 penetrating the interlayer dielectric film ITL. The pixel connection electrode PCE may be connected to the first electrode E11 of the first transistor T1 through a fourth contact hole CT4 penetrating through the interlayer dielectric film ITL. In other words, the pixel connection electrode PCE may be connected to a part of the first area of the first active layer ACT1 that corresponds to the first electrode E11 of the first transistor T1 through the fourth contact hole CT4. As shown in FIG. 14, the second capacitor C2 may be formed between the first upper driving voltage line VDLb and the first active layer ACT1 overlapping each other in the third direction. It should be noted that the first contact hole CT1, the second contact hole CT2, the third contact hole CT3 and the fourth contact hole CT4 may be of the first-type contact holes CTa described above.

As shown in FIG. 14, a planarization layer VIA may be disposed on the fourth conductive layer 444. The planarization film VIA may be disposed on the entire surface of the substrate SUB including the fourth conductive layer 444. For example, as shown in FIG. 14, the planarization film VIA may be disposed on the entire surface of the substrate SUB that includes the first upper driving voltage line VDLb, the counter gate connection electrode GCEb, the first gate connection electrode GCE1 and the pixel connection electrode PCE. The planarization film VIA may include an organic film such as an acryl resin, an epoxy resin, a phenolic resin, a polyamide resin, and/or a polyimide resin.

The emission layer EMTL including the fifth conductive layer 555 may be disposed on the planarization film VIA. For example, as shown in FIG. 14, the pixel electrode PE may be disposed as the fifth conductive layer 555 on the planarization film VIA. In the example shown in FIG. 14, the pixel electrodes PE are disposed on the planarization film VIAl. As shown in FIG. 14, the pixel electrode PE may be connected to the pixel connection electrode PCE through a fifth contact hole CT5 penetrating the planarization film VIA. It should be noted that the fifth contact hole CT5 may be of the second-type contact holes CTb described above.

The emission layer EMTL described above may further include multiple light-emitting elements LEL and a bank PDL (or pixel-defining film) in addition to the fifth conductive layer 555.

The light-emitting elements LEL may include, for example, a first light-emitting element, a second light-emitting element, and a third light-emitting element. The first light-emitting element may include a first pixel electrode, a first emissive layer, and a common electrode CM. The second light-emitting element may include a second pixel electrode, a second emissive layer, and a common electrode CM. The third light-emitting element may include a third pixel electrode, a third emissive layer, and a common electrode CM.

The light-emitting element LEL may include the pixel electrode PE, the emissive layer EL, and the common electrode CM. In the emission area EA, the pixel electrode PE, the emissive layer EL and the common electrode CM are stacked on one another sequentially, so that holes from the pixel electrode PE and electrons from the common electrode CM are combined with each other in the emissive layer to emit light. In this instance, the pixel electrode PE may be an anode electrode of the light-emitting element LEL, and the common electrode CM may be a cathode electrode of the light-emitting element LEL.

In the top-emission structure where light exits from the emissive layer EL toward the common electrode CM, the pixel electrode may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/Al/ITO), an APC alloy and a stack structure of APC alloy and ITO (ITO/APC/ITO) in order to increase the reflectivity. The APC alloy may be an alloy of silver (Ag), palladium (Pd) and copper (Cu).

The bank PDL (or pixel-defining film) may define the emission areas EA of the pixels. To this end, the bank PDL may be disposed to expose a part of the first pixel electrode on the planarization film. The bank PDL may cover an edge of the first pixel electrode. Although not shown in the drawings, the bank PDL may be disposed in the fourth contact hole CT4 penetrating the planarization film VIA. Accordingly, the fourth contact hole CT4 penetrating the planarization film VIA may be filled with the bank PDL. The bank PDL may be formed of an organic layer such as an acryl resin, an epoxy resin, a phenolic resin, a polyamide resin, and/or a polyimide resin.

As shown in FIG. 14, a spacer SPC may be disposed on the bank PDL. The spacer SPC may support a mask during a process of fabricating the emissive layer EL. The spacer SPC may be formed of an organic layer such as an acryl resin, an epoxy resin, a phenolic resin, a polyamide resin, and/or a polyimide resin.

The emissive layer EL may be formed on the pixel electrode PE. The emissive layer EL may include an organic material to emit light of a certain color. For example, the emissive layer EL may include a hole transporting layer, an organic material layer, and an electron transporting layer. The organic material layer may include a host and a dopant. The organic material layer may include a material that emits a predetermined or selected light, and may be formed using a phosphor or a fluorescent material.

For example, the organic material layer of the first emissive layer in the first emission area that emits light of the first color may be a phosphor that includes a host material including carbazole biphenyl (CBP) or mCP(1,3-bis (carbazol-9-yl), and a dopant including at least one of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum). In other embodiments, the organic material layer of the first emissive layer of the first emission area may be, but is not limited to, a fluorescent material including PBD: Eu(DBM)3(Phen) or perylene.

The organic material layer of the second emissive layer of the second emission area, which emits light of the second color, may be a phosphor that includes a host material including CBP or mCP, and a dopant material including ir(ppy)3(fac tris(2-phenylpyridine)iridium). In other embodiments, the organic material layer of the second emissive layer of the second emission area emitting light of the second color may be, but is not limited to, a fluorescent material including Alq3(tris (8-hydroxyquinolino)aluminum).

The organic material layer of the emissive layer of the third emission area, which emits light of the third color, may be, but is not limited to, a phosphor that includes a host material including CBP or mCP, and a dopant material including (4,6-F2ppy)2Irpic or L2BD111.

The common electrode CM may be disposed on the first, second and third emissive layers (e.g., EL). The common electrode CM may be disposed to cover the first, second and third emissive layers. The common electrode CM may be a common layer disposed across the first to third emissive layers. A capping layer may be formed on the common electrode CM.

In the top-emission structure, the common electrode CM may be formed of a transparent conductive material (TCP) such as ITO and IZO that can transmit light, or a semi-transmissive conductive material such as magnesium (Mg), silver (Ag) and an alloy of magnesium (Mg) and silver (Ag). In case that the common electrode CM is formed of a semi-transmissive metal material, the light extraction efficiency can be increased by using microcavities.

The encapsulation layer ENC may be formed on the emission layer EMTL. The encapsulation layer ENC may include one or more inorganic films TFE1 and TFE3 to prevent permeation of oxygen or moisture into the emission layer EMTL. The encapsulation layer ENC may include at least one organic film to protect the emission layer EMTL from particles such as dust. For example, the encapsulation layer ENC may include a first inorganic encapsulation film TFE1, an organic encapsulation film TFE2 and a second inorganic encapsulation film TFE3.

The first inorganic encapsulation film TFE1 may be disposed on the common electrode CM, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

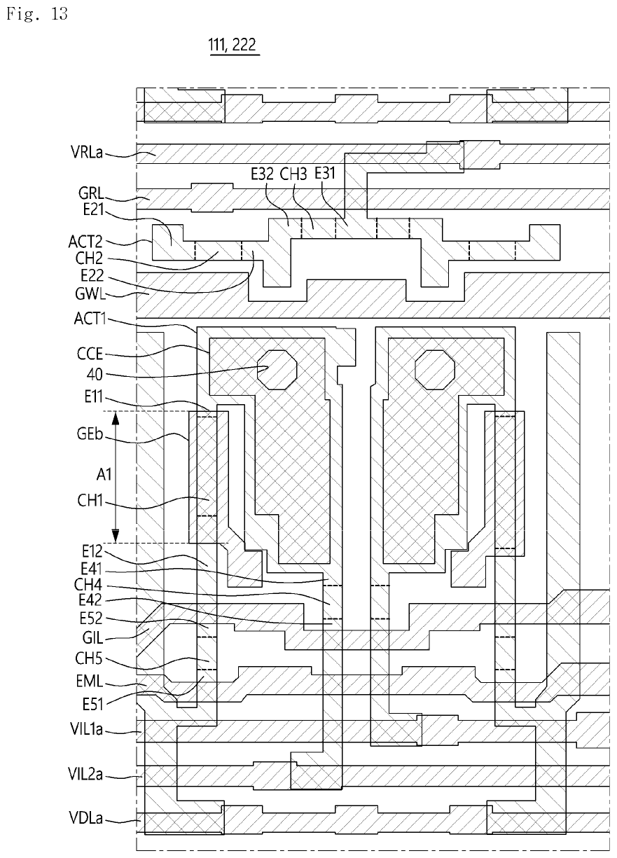

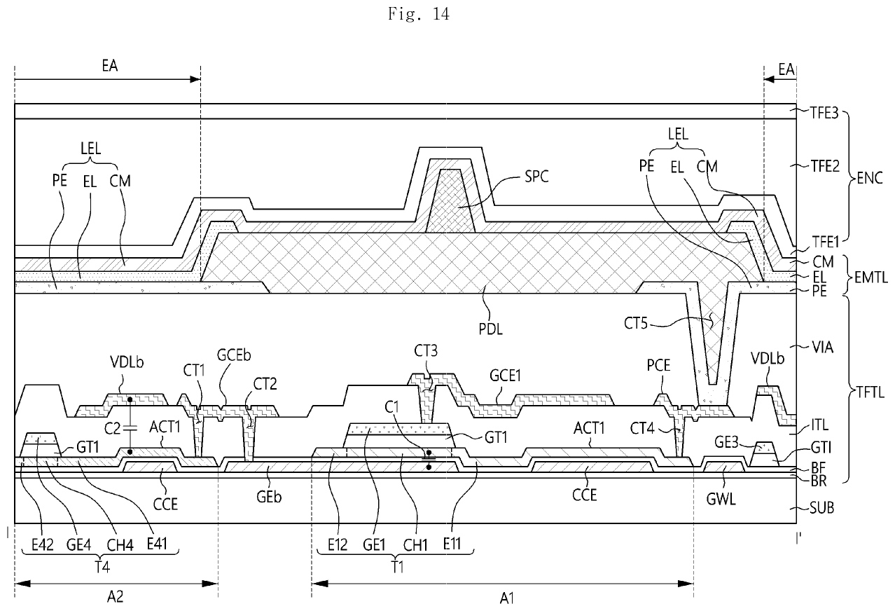

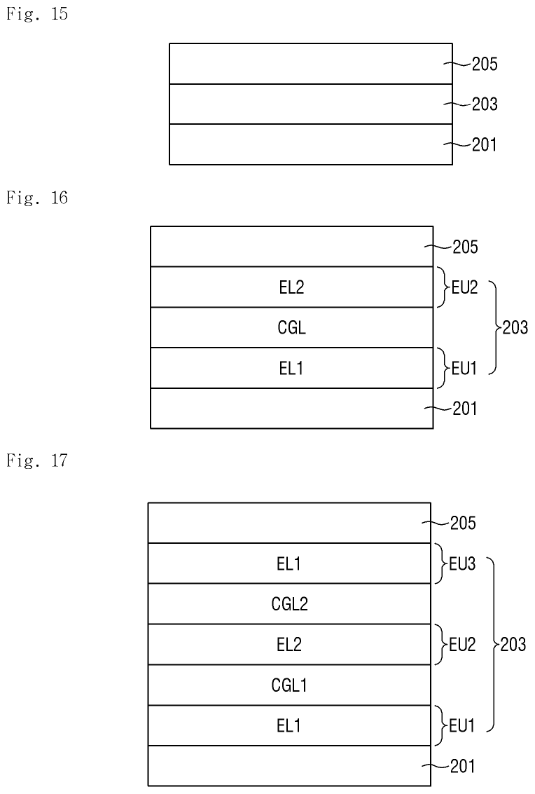

Other structures of a light-emitting element LEL (e.g., see FIG. 14) will be described with reference to FIGS. 15 to 22.

FIG. 15 is a schematic cross-sectional view showing a structure of a display device according to an embodiment of the disclosure. FIGS. 16 to 19 are schematic cross-sectional views illustrating structures of light-emitting elements according to embodiments.

Referring to FIG. 15, a light-emitting element (e.g., an organic light-emitting diode) according to an embodiment may include a pixel electrode 201, a common electrode 205, and an intermediate layer 203 between the pixel electrode 201 and the common electrode 205.

The pixel electrode 201 may include a transparent conductive oxide such as indium tin oxide (ITO), indium zinc oxide (IZO), zinc oxide (ZnO), indium oxide (In₂O₃), indium gallium oxide (IGO), and/or aluminum zinc oxide (AZO). The pixel electrode 201 may include a reflective layer containing silver (Ag), magnesium (Mg), aluminum (Al), platinum (Pt), palladium (Pd), gold (Au), nickel (Ni), neodymium (Nd), iridium (Ir), chrome (Cr), or a compound thereof. For example, the pixel electrode 201 may have a three-layer structure of ITO/Ag/ITO.

The common electrode 205 may be disposed on the intermediate layer 203. The common electrode 205 may include a method having a low work function, an alloy, an electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a transflective electrode, and/or a reflective electrode.

The intermediate layer 203 may include a polymer or a low molecular weight organic material that emits light of a predetermined or selected color. In addition to a variety of organic materials, the intermediate layer 203 may further include metal-containing compounds such as organometallic compounds, inorganic materials such as quantum dots, etc.

According to an embodiment, the intermediate layer 203 may include an emissive layer and a first functional layer and a second functional layer respectively disposed under and on the emissive layer. The first functional layer may include, for example, a hole transport layer HTL or may include a hole transport layer and a hole injection layer HIL. The second functional layer may be an optional element disposed on the emissive layer. For example, the intermediate layer 203 may or may not include the second functional layer. The second functional layer may include an electron transport layer ETL and/or an electron injection layer EIL.

According to an embodiment, the intermediate layer 203 may include two or more emitting units sequentially stacked between the pixel electrode 201 and the common electrode 205, and a charge generation layer CGL disposed between the two emitting units. In case that the intermediate layer 203 includes the emitting units and the charge generation layer, the light-emitting element (e.g., organic light-emitting diode) may have a tandem structure. The light-emitting element (e.g., an organic light-emitting diode) can improve the color purity and the emission efficiency by employing a stack structure of multiple emitting units.

An emitting unit may include an emissive layer, and a first functional layer and a second functional layer respectively disposed under and on the emissive layer. The charge generation layer CGL may include a negative charge generation layer and a positive charge generation layer. The emission efficiency of an organic light-emitting diode, which is a tandem light-emitting element having multiple emissive layers, can be further increased by the negative charge generating layer and the positive charge generating layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

According to the embodiment, as shown in FIG. 16, the light-emitting element (e.g., an organic light-emitting diode) may include a first emitting unit EU1 including a first emissive layer EL1 and a second emitting layer EL2 including a second emissive layer EL2 stacked on each other. The charge generation layer CGL may be disposed between the first emitting unit EU1 and the second emitting unit EU2. For example, the light-emitting element (e.g., an organic light-emitting diode) may include a pixel electrode 201, a first emissive layer EL1, a charge generation layer CGL, a second emissive layer EL2, and a common electrode 205 sequentially stacked on one another. A first functional layer and a second functional layer may be disposed under and on the first emissive layer EL1, respectively. A first functional layer and a second functional layer may be disposed under and on the second emissive layer EL2, respectively. The first emissive layer EL1 may be a blue emissive layer, and the second emissive layer EL2 may be a yellow emissive layer.

According to an embodiment, as shown in FIG. 17, the light-emitting element (e.g., an organic light-emitting diode) may include a first emitting unit EU1 including a first emissive layer EL1, a third light-emitting unit EU3, and a second emitting layer EL2 including a second emissive layer EL2. The first charge generation layer CGL1 may be disposed between the first emitting unit EU1 and the second emitting unit EU2, and the second charge generation layer CGL2 may be disposed between the second emitting unit EU2 and the third emitting unit EU3. For example, the light-emitting element (e.g., organic light-emitting diode) may include a pixel electrode 201, a first emissive layer EL1, a first charge generation layer CGL1, a second emissive layer EL2, a second charge generation layer CGL2, a first emissive layer EL1, and a common electrode 205, which are stacked on one another in this order. A first functional layer and a second functional layer may be disposed under and on the first emissive layer EL1, respectively. A first functional layer and a second functional layer may be disposed under and on the second emissive layer EL2, respectively. The first emissive layer EL1 may be a blue emissive layer, and the second emissive layer EL2 may be a yellow emissive layer.

According to an embodiment of the disclosure, the second emitting unit EU2 of the light-emitting element (e.g., organic light-emitting diode) may further include a third emitting layer EL3 and/or a fourth emitting layer EL4 in direct contact with the second emitting unit EU2 under and/or on the second emitting layer EL2 in addition to the second emitting layer EL2. As used herein, the phrase that the third emitting layer EL3 and/or the fourth emitting layer EL4 are in direct contact with the second emitting unit EU2 may mean that no other layer is disposed between the second emitting layer EL2 and the third emitting layer EL3 and/or between the second emitting layer EL2 and the fourth emitting layer EL4. The third emissive layer EL3 may be a red emissive layer, and the fourth emissive layer EL4 may be a green emissive layer.

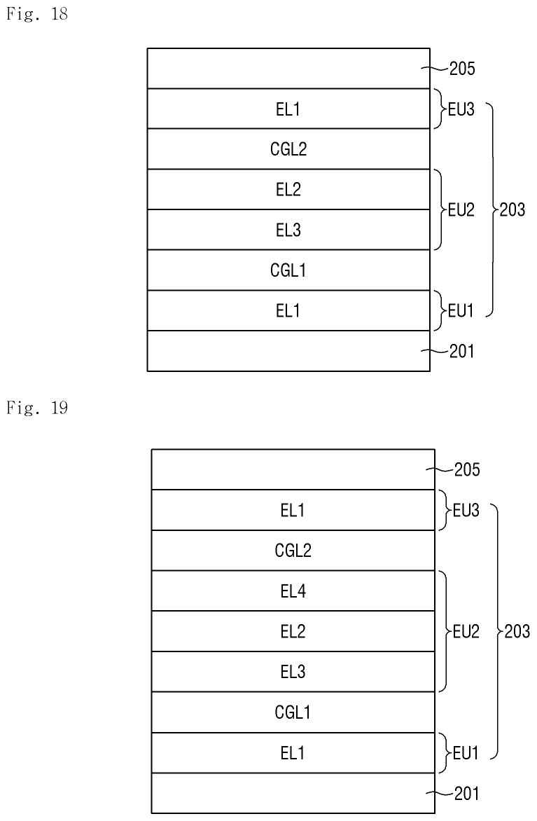

For example, as shown in FIG. 18, the light-emitting element (e.g., organic light-emitting diode) may include a pixel electrode 201, a first emissive layer EL1, a first charge generation layer CGL1, a third emissive layer EL3, a second emissive layer EL2, a second charge generation layer CGL2, a first emissive layer EL1, and a common electrode 205, which are stacked on one another in this order. In other embodiments, as shown in FIG. 19, the light-emitting element (e.g., organic light-emitting diode) may include a pixel electrode 201, a first emissive layer EL1, a first charge generation layer CGL1, a third emissive layer EL3, a second emissive layer EL2, a fourth emissive layer EL4, a second charge generation layer CGL2, a first emissive layer EL1, and a common electrode 205, which are stacked on one another in this order.

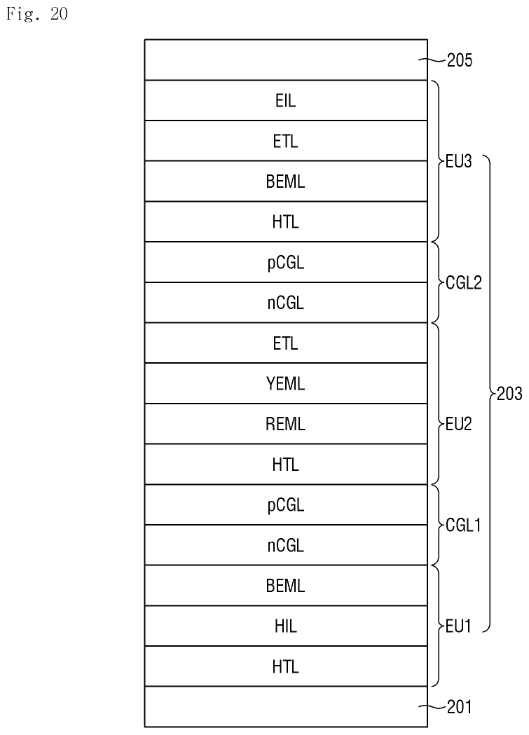

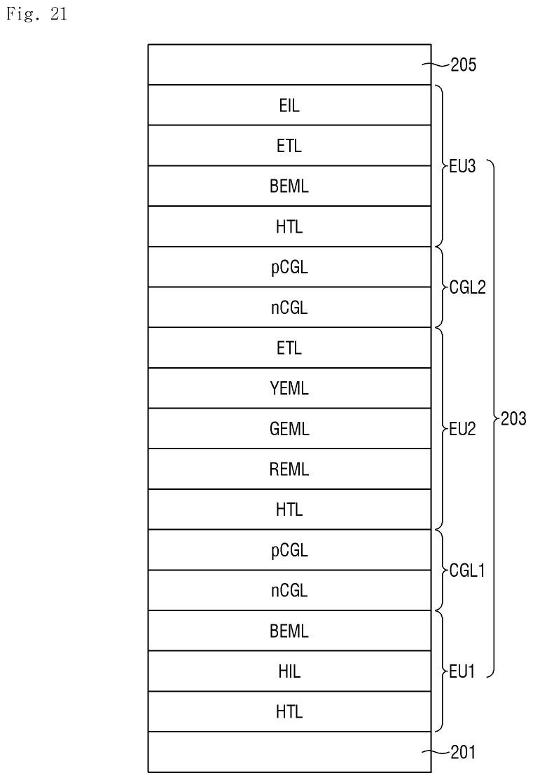

FIG. 20 is a schematic cross-sectional view showing an example of the organic light-emitting diode of FIG. 18. FIG. 21 is a schematic cross-sectional view showing an example of the organic light-emitting diode of FIG. 19.

Referring to FIG. 20, the light-emitting element (e.g., an organic light-emitting diode) may include a first emitting unit EU1, a second emitting unit EU2, and a third emitting unit EU3 stacked on one another in this order. The first charge generation layer CGL1 may be disposed between the first emitting unit EU1 and the second emitting unit EU2, and the second charge generation layer CGL2 may be disposed between the second emitting unit EU2 and the third emitting unit EU3. Each of the first charge generation layer CGL1 and the second charge generation layer CGL2 may include a negative charge generation layer nCGL and a positive charge generation layer pCGL.

The first emitting unit EU1 may include a blue emissive layer BEML. The first emitting unit EU1 may further include a hole injection layer HIL and a hole transport layer HTL between the pixel electrode 201 and the blue emissive layer BEML. According to an embodiment of the disclosure, a p-doped layer may be further included between the hole injection layer HIL and the hole transport layer HTL. The p-doped layer may be formed by doping the hole injection layer HIL with a p-type doping material. According to an embodiment of the disclosure, at least one of a blue light auxiliary layer, an electron blocking layer and a buffer layer may be further included between the blue emissive layer BEML and the hole transport layer HTL. The blue light auxiliary layer can increase the emission efficiency of the blue emissive layer BEML. The blue light auxiliary layer can increase the emission efficiency of the blue emissive layer BEML by adjusting the hole charge balance. The electron blocking layer may be used to prevent injection of electrons into the hole transport layer HTL. The buffer layer may be used to compensate for a resonance distance according to a wavelength of light emitted from the emissive layer.

The second emitting unit EU2 may include a yellow emissive layer YEML and a red emissive layer REML directly in contact with the yellow emissive layer YEML under the yellow emissive layer YEML. The second emitting unit EU2 may further include a hole transport layer HTL between the positive charge generation layer pCGL of the first charge generation layer CGL1 and the red emissive layer REML, and an electron transport layer ETL between the yellow emissive layer YEML and the negative charge generation layer nCGL of the second charge generation layer CGL2.

The third emitting unit EU3 may include a blue emissive layer BEML. The third emitting unit EU3 may further include a hole transport layer HTL between the positive charge generation layer pCGL of the second charge generation layer CGL2 and the blue emissive layer BEML. The third emitting unit EU3 may further include an electron transport layer ETL and an electron injection layer EIL between the blue emissive layer BEML and the common electrode 205. The electron transport layer ETL may be made up of a single layer or multiple layers. According to an embodiment of the disclosure, at least one of a blue light auxiliary layer, an electron blocking layer and a buffer layer may be further included between the blue emissive layer BEML and the hole transport layer HTL. At least one of the hole blocking layer and the buffer layer may be further included between the blue emissive layer BEML and the electron transport layer ETL. The hole blocking layer may be used to prevent injection of holes into the electron transport layer ETL.

The light-emitting element (e.g., organic light-emitting diode) shown in FIG. 21 is substantially identical to the light-emitting element (e.g., organic light-emitting diode) shown in FIG. 20 except for a stack structure of a second emitting unit EU2. Referring to FIG. 21, the second emitting unit EU2 may include a green emissive layer GEML, a red emissive layer REML directly in contact with the green emissive layer GEML under the green emissive layer GEML, and a yellow emissive layer YEML directly in contact with the green emissive layer GEML on the green emissive layer GEML. The second emitting unit EU2 may further include a hole transport layer HTL between the positive charge generation layer pCGL of the first charge generation layer CGL1 and the red emissive layer REML, and an electron transport layer ETL between the yellow emissive layer YEML and the negative charge generation layer nCGL of the second charge generation layer CGL2.

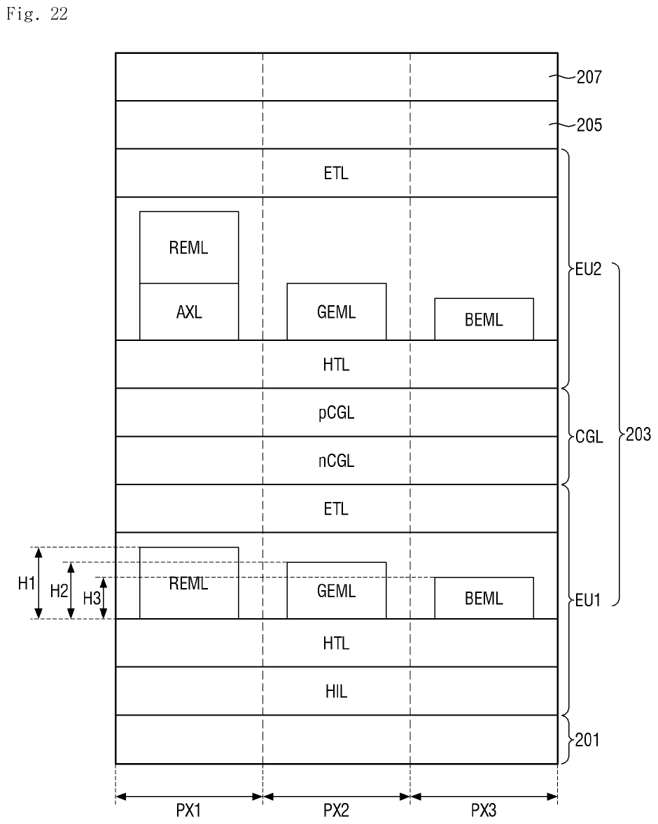

FIG. 22 is a schematic cross-sectional view showing a structure of a pixel of a display device according to an embodiment of the disclosure.

Referring to FIG. 22, a display panel 100 of a display device 10 may include multiple pixels (e.g., sub-pixels). The pixels may include a first pixel PX1, a second pixel PX2 and a third pixel PX3. Each of the first pixel PX1, the second pixel PX2 and the third pixel PX3 may include a pixel electrode 201, a common electrode 205 and an intermediate layer 203. According to an embodiment of the disclosure, the first pixels PX1 may be red pixels, the second pixels PX2 may be green pixels, and the third color pixels PX3 may be blue pixels.

The pixel electrode 201 may be independently disposed in each of the first pixel PX1, the second pixel PX2 and the third pixel PX3.

The intermediate layer 203 of each of the first pixel PX1, the second pixel PX2 and the third pixel PX3 may include a first emitting unit EU1, a second emitting unit EU2, and a charge generation layer CGL between the first emitting unit EU1 and the second emitting unit EU2, which are stacked on one another in this order. The charge generation layer CGL may include a negative charge generation layer nCGL and a positive charge generation layer pCGL. The charge generation layer CGL may be a common layer continuously formed across the first pixel PX1, the second pixel PX2 and the third pixel PX3.

The first emitting unit EU1 of the first pixel PX1 may include a hole injection layer HIL, a hole transport layer HTL, a red emissive layer REML, and an electron transport layer ETL sequentially stacked on the pixel electrode 201. The first emitting unit EU1 of the second pixel PX2 may include a hole injection layer HIL, a hole transport layer HTL, a green emissive layer GEML, and an electron transport layer ETL sequentially stacked on the pixel electrode 201. The first emitting unit EU1 of the third pixel PX3 may include a hole injection layer HIL, a hole transport layer HTL, a blue emissive layer BEML, and an electron transport layer ETL sequentially stacked on the pixel electrode 201. Each of the hole injection layer HIL, the hole transport layer HTL and the electron transport layer ETL of the first emitting units EU1 may be a common layer extended across the first pixel PX1, the second pixel PX2 and the third pixel PX3.

The second emitting unit EU2 of the first pixel PX1 may include a hole transport layer HTL, an auxiliary layer AXL, a red emissive layer REML, and an electron transport layer ETL sequentially stacked on the charge generation layer CGL. The second emitting unit EU2 of the second pixel PX2 may include a hole transport layer HTL, a green emissive layer GEML, and an electron transport layer ETL sequentially stacked on the charge generation layer CGL. The second emitting unit EU2 of the third pixel PX3 may include a hole transport layer HTL, a blue emissive layer BEML, and an electron transport layer ETL sequentially stacked on the charge generation layer CGL. Each of the hole transport layer HTL and the electron transport layer ETL of the second emitting units EU2 may be a common layer extended across the first pixel PX1, the second pixel PX2 and the third pixel PX3. According to an embodiment of the disclosure, at least one of a hole blocking layer and a buffer layer may be between the emissive layer and the electron transport layer ETL in the second emitting units EU2 of the first pixel PX1, the second pixel PX2 and the third pixel PX3.

A thickness H1 of the red emissive layer REML, a thickness H2 of the green emissive layer GEML, and a thickness H3 of the blue emissive layer BEML may be determined depending on the resonance distance. The auxiliary layer AXL may be additionally disposed to adjust the resonance distance and may include a material for adjusting resonance. For example, the auxiliary layer AXL may include the same material as the hole transport layer HTL.

Although the auxiliary layer AXL is disposed only in the first pixel PX1 in the example shown in FIG. 22, the embodiments of the disclosure are not limited thereto. For example, the auxiliary layer AXL may be disposed in at least one of the first pixel PX1, the second pixel PX2 and the third pixel PX3 in order to match the resonance distance of each of the first pixel PX1, the second pixel PX2 and the third pixel PX3.

The display panel 100 of the display device 10 may further include a capping layer 207 disposed outside the common electrode 205. The capping layer 207 may be used to improve the emission efficiency by the principle of constructive interference. Accordingly, the out-coupling efficiency of the light-emitting element (e.g., organic light-emitting diode) can be increased, and thus the emission efficiency of the light-emitting element (e.g., organic light-emitting diode) can be improved.

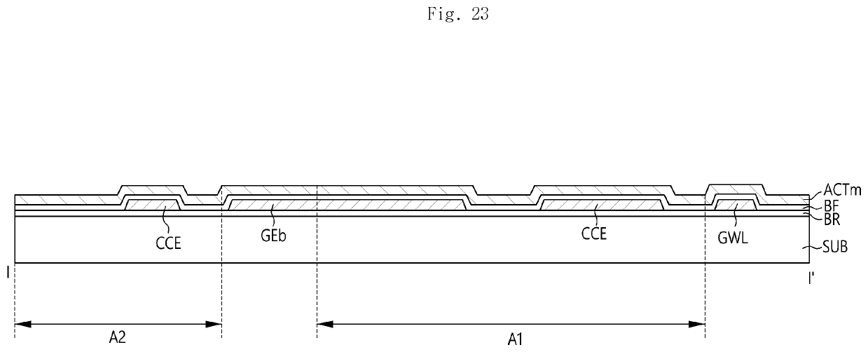

FIGS. 23 to 35 are schematic cross-sectional views showing processing steps for illustrating a method of fabricating a display device according to an embodiment of the disclosure.

Initially, as shown in FIG. 23, a substrate including a first area A1 and a second area A2 may be prepared. The first area A1 of the substrate may correspond to the first area A1 of the first active layer ACT1 described above, and the second area A2 of the substrate SUB may correspond to the second area of the first active layer ACT1 described above.

Subsequently, a barrier film BR may be formed on the substrate SUB. For example, the barrier film BR may be formed on the entire surface of the substrate SUB.

Subsequently, a first conductive material layer may be formed on the entire surface of the substrate SUB including the barrier film BR, and the first conductive material layer may be patterned via a photolithography process and an etching process. By patterning the first conductive material layer, a first conductive layer 111, for example, a capacitor electrode CCE, a gate counter electrode GEb, and a first gate line GWL may be formed on the barrier film BR.

Subsequently, a buffer film BF may be formed on the entire surface of the substrate SUB including the first conductive layer 111. Subsequently, a second conductive material layer ACTm may be formed on the buffer film BF. The second conductive material layer ACTm may include, for example, indium-gallium-zinc-oxide (IGZO) or indium-gallium-zinc-tin oxide (IGZTO).

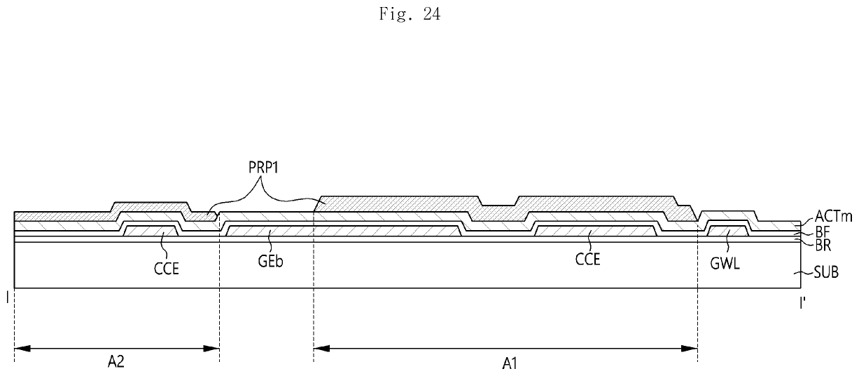

Subsequently, as shown in FIG. 24, a first photoresist pattern PRP1 having different thicknesses may be formed on the second conductive material layer ACTm. For example, the first photoresist pattern PRP1 may be formed in the first and second areas A1 and A2 of the first active layer ACT1, which has a greater thickness in the first area A1. As such, the first photoresist pattern PRP1 having different thicknesses in the first area A1 and the second area A2 may be formed via a single mask process by using, for example, a half-tone mask (or a diffraction mask). The half-tone mask may include a transparent area through which light is transmitted, a blocking area through which light is blocked, and a semi-transparent area through which light is partially transmitted. The semi-transparent area may include multiple slits or a semi-transparent film. Such a half-tone mask process will be described in more detail as follows:

Initially, a photoresist layer may be formed on a second conductive material layer ACTm to be patterned. This photoresist layer may be formed on the entire surface of the substrate SUB including the second conductive material layer ACTm. Subsequently, the above-described half-tone mask may be placed above the photoresist layer. The blocking areas of the half-tone mask may be disposed in line with the first area of the first active layer ACT1 and the second active layer ACT2, and the semi-transparent area of the half-tone mask may be disposed in line with the second area of the first active layer ACT1. Subsequently, light such as ultraviolet light may be selectively irradiated onto the photoresist layer through the half-tone mask to expose the photoresist layer to light. Subsequently, in case that the exposed photoresist layer is developed, as shown in FIG. 24, the first photoresist patterns PRP1 having different thicknesses may be formed on the second conductive material layer ACTm. In other words, a portion of the photoresist layer in line with the blocking area may be removed, a part of the photoresist layer in line with the transparent area may remain substantially intact, and a part of the photoresist layer in line with the semi-transparent area may be partially removed. Accordingly, the thickness of the first photoresist pattern PRP1 may be lower in the second area A2 in line with the semi-transparent area of the half-tone mask than in the first area A1 in line with the blocking area of the half-tone mask. In other words, the first photoresist pattern PRP1 may have a greater thickness in the first area A1 of the first and second areas A1 and A2. For example, the thickness of the first photoresist pattern PRP1 in the first area A1 may be approximately twice the thickness of the first photoresist pattern PRP1 in the second area A2. Herein, the thickness may refer to the size in the third direction. The thickness of the first photoresist pattern PRP1 on the second active layer ACT2 may be equal to the thickness of the first area, for example.

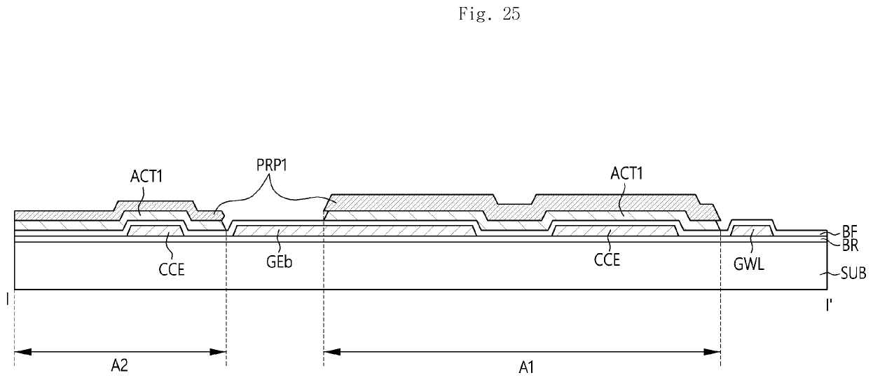

Thereafter, as shown in FIG. 25, an etching process may be carried out using the first photoresist pattern PRP1 as a mask, thereby patterning the second conductive material layer ACTm. As the second conductive material layer ACTm is patterned, the first active layer ACT1 and the second active layer ACT2 may be formed on the buffer film BF.

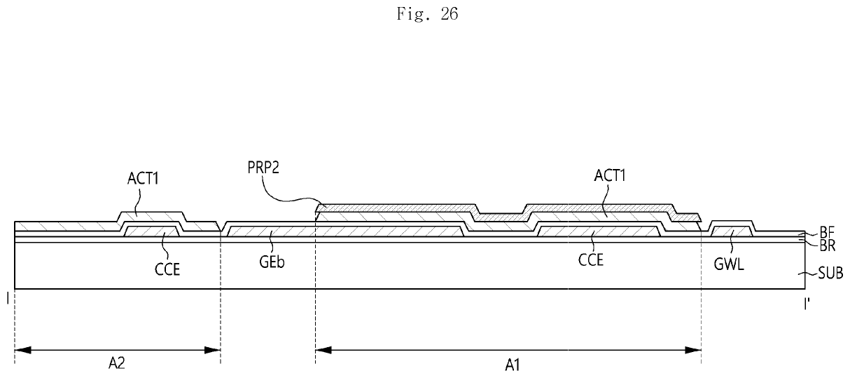

Subsequently, as shown in FIG. 26, an ashing process may be carried out to form a second photoresist pattern PRP2. This ashing process may be carried out so that the part of the first photoresist pattern PRP1 having lower thickness can be completely removed. While the part of the first photoresist pattern PRP1 having a lower thickness in the second area A2 may be completely removed during the ashing process, the part of the first photoresist pattern PRP1 in the first area A1 may be removed by the thickness of the first photoresist pattern PRP1. Accordingly, the first photoresist pattern PRP1 of the first area A1 may remain on the second area of the first active layer ACT1 with a thickness of approximately half the initial thickness. The first photoresist pattern PRP1 of the second active layer ACT2 may remain on the second active layer ACT2 with a thickness of approximately half the initial thickness. The first photoresist pattern PRP1 of the second area A2 may be removed to expose the second area A2 of the first active layer ACT1.

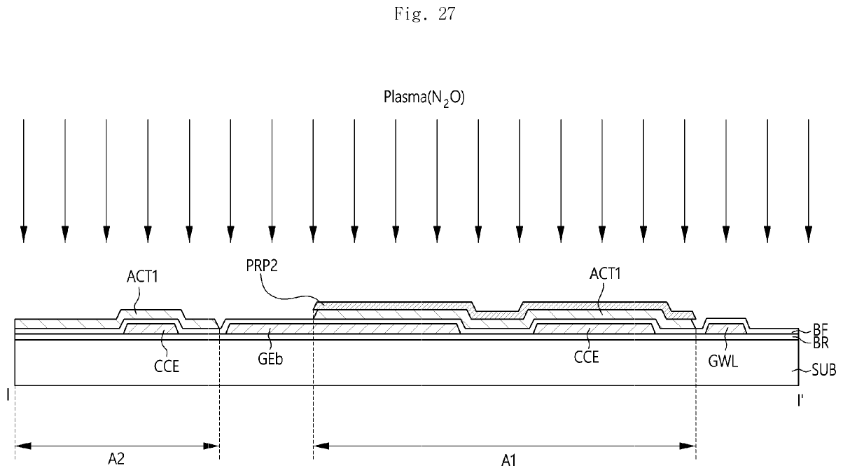

Subsequently, as shown in FIG. 27, plasma treatment may be carried out using the second photoresist pattern PRP2 as a mask. For example, plasma treatment using N₂O gas as a plasma gas may be carried out. By this plasma treatment, nitrogen may be selectively injected only in the portion of the first active layer ACT1 exposed in the second region A2. In other words, nitrogen may be selectively injected into only the second area A2 of the first active layer ACT1. On the other hand, no nitrogen may be injected into the first area A1 of the first active layer ACT1 and the second active layer ACT2 blocked by the second photoresist pattern PRP2. The plasma treatment may be carried out, for example, in the same chamber as the ashing process described above.

Subsequently, as shown in FIG. 28, the second photoresist pattern PRP2 may be removed via a strip process.

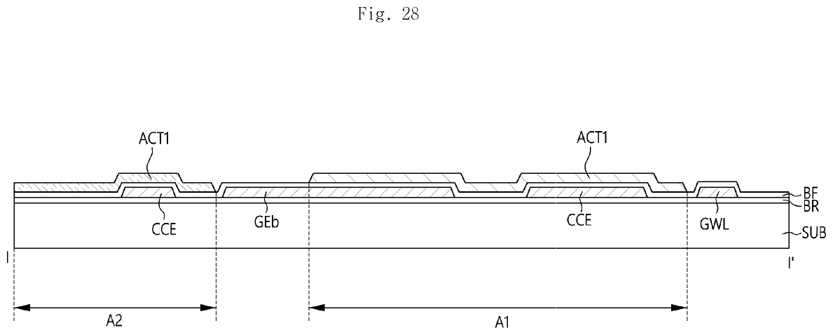

Subsequently, as shown in FIG. 29, an insulating material layer GTIm may be formed on the entire surface of the substrate SUB including the first active layer ACT1 and the second active layer ACT2.

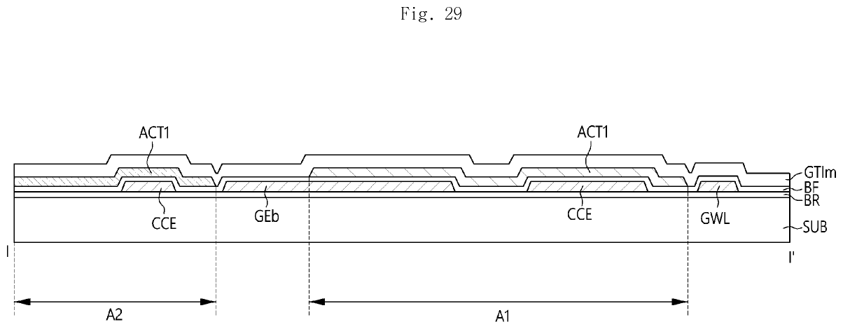

Subsequently, a third conductive material layer may be formed on the entire surface of the substrate SUB including the insulating material layer GTIm, and the third conductive material layer may be patterned via a photolithography process and an etching process. As the third conductive material layer is patterned, as shown in FIG. 30, a third conductive layer 333, for example, a fourth gate electrode GE4, a first gate electrode GE1 and a third gate electrode GE3 may be formed on the insulating material layer GTIm. The fourth gate electrode GE4 may be formed on an insulating material layer GTIm so that it overlaps the fourth channel region CH4 of the first active layer ACT1. The first gate electrode GE1 may be formed on a second insulating material layer GTI2a so that it overlaps the first channel region CH1 of the first active layer ACT1. The third gate electrode GE3 may be formed on the insulating material layer GTIm so that it overlaps the third channel region CH3 of the second active layer ACT2.

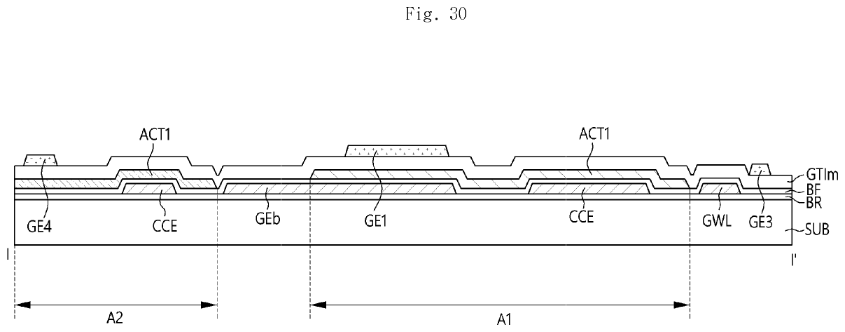

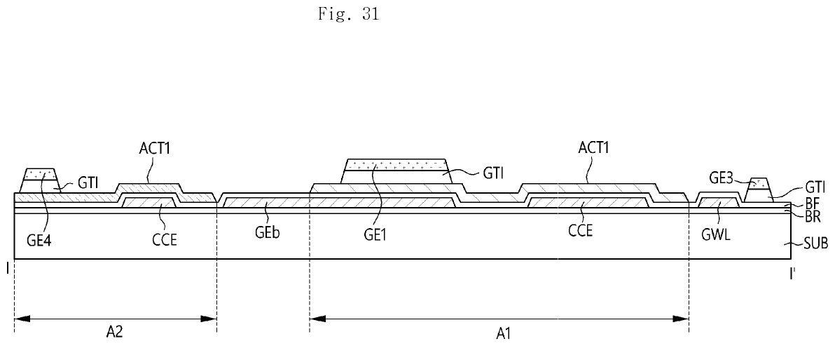

Subsequently, an etching process may be carried out using the third conductive layer 333 (e.g., the fourth gate electrode GE4, the first gate electrode GE1, and the third gate electrode GE3) as a mask (e.g., a hard mask). As a part of the insulating material layer GTIm that is not covered by the third conductive layer 333 is removed during the etching process, a gate insulator GTI may be formed on the first active layer ACT1 and the second active layer ACT2, as shown in FIG. 31. As in the example shown in FIG. 31, the gate insulator GTI may be disposed between the fourth gate electrode GE4 and the first active layer ACT1, between the first gate electrode GE1 and the first active layer ACT1, and between the third gate electrode GE3 and the second active layer ACT2.

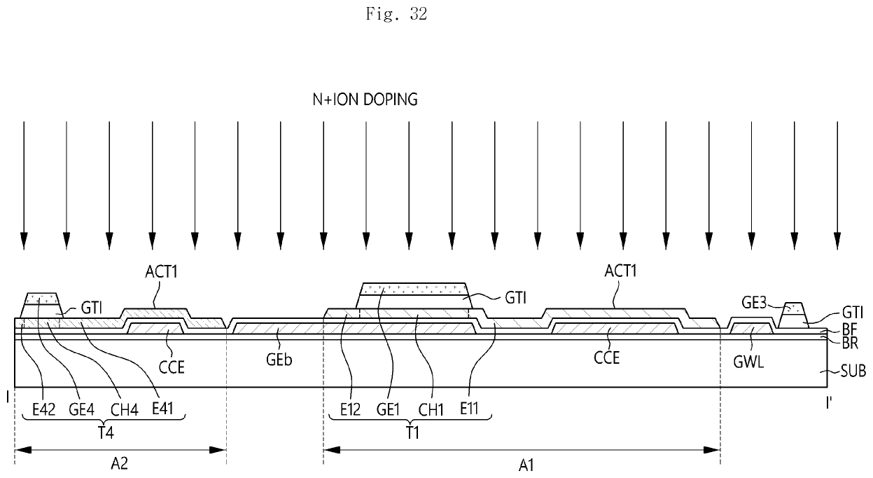

Subsequently, as shown in FIG. 32, an ion (e.g., n+ ion) doping process may be carried out using the third conductive layer 333 (e.g., the fourth gate electrode GE4, the first gate electrode GE1, and the third gate electrode GE3) as a mask. Via the ion doping process, channel regions CH1 to CH5 of the first to fifth transistors T1 to T5 may be formed in the first active layer ACT1 and the second active layer ACT2, and the regions except the channel regions CH1 to CH5 may have conductivity. For example, ions may be implanted into regions of the first active layer ACT1 and the second active layer ACT2 that are not covered by the third conductive layer 333, and accordingly the regions may have conductivity. On the other hand, no ions may be implanted into regions of the first active layer ACT1 and the second active layer ACT2 that are covered by the third conductive layer 333, and accordingly the regions may be defined as channel regions. As in the example shown in FIG. 32, the fourth channel region CH4, the first electrode E41 and the second electrode E42 are formed in the second area A2 of the first active layer ACT1, and the first channel region CH1, the first electrode E11 and the second electrode E12 may be formed in the first area A1 of the first active layer ACT1. After the ion implantation process described above, an annealing process may be carried out.

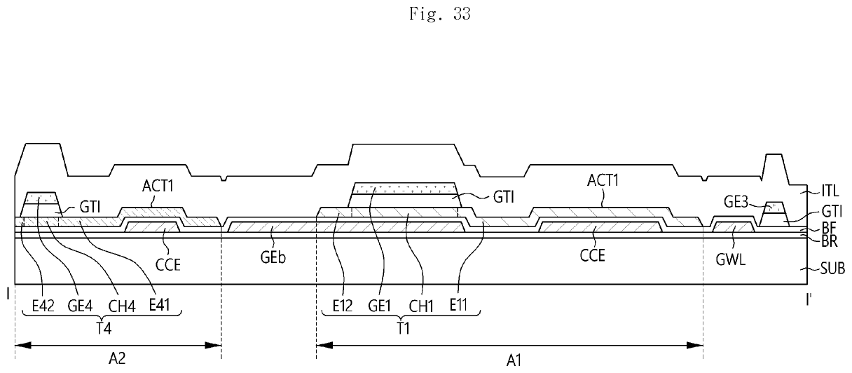

Subsequently, as shown in FIG. 33, an interlayer dielectric film ITL may be formed on the entire surface of the substrate SUB.

Subsequently, as shown in FIG. 34, a first contact hole CT1, a third contact hole CT3 and a fourth contact hole CT4 penetrating the interlayer dielectric film ITL, and a second contact hole CT2 penetrating the interlayer dielectric film ITL and the buffer film BF may be formed via a photolithography and etching process. The first electrode E41 may be exposed in the second area A2 of the first active layer ACT1 by the first contact hole CT1. The counter gate electrode GEb may be exposed by the second contact hole CT2. The first gate electrode GE1 may be exposed by the third contact hole CT3. The first electrode E11 may be exposed in the second area A2 of the first active layer ACT1 by the fourth contact hole CT4.

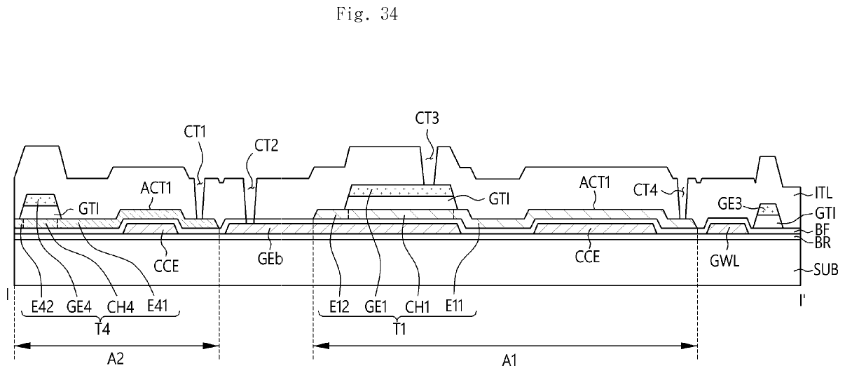

Subsequently, a fourth conductive material layer may be formed on the entire surface of the substrate SUB including the interlayer dielectric film ITL, and the fourth conductive material layer may be patterned via a photolithography process and an etching process. As the fourth conductive material layer is patterned, a fourth conductive layer 444, for example, as shown in FIG. 35, a first upper driving voltage line VDLb, a counter gate connection electrode GCEb, a first gate connection electrode GCE1 and a pixel connection electrode PCE may be formed on the interlayer dielectric film ITL. The counter gate connection electrode GCEb may be connected to the first electrode E41 in the second region A2 of the first active layer ACT1 through the first contact hole CT1. The counter gate connection electrode GCEb may be connected to the counter gate electrode GEb through the second contact hole CT2. The first gate connection electrode GCE1 may be connected to the first gate electrode GE1 through the third contact hole CT3. The pixel connection electrode PCE may be connected to the first electrode E11 in the first area A1 of the first active layer ACT1 through the fourth contact hole CT4.

Subsequently, on the fourth conductive layer 444 (e.g., VDLb, CGEb, GCE1 and PCE), as shown in FIG. 14, a planarization layer VIA, a fifth contact hole CT5, a fifth conductive layer 555 (e.g., a pixel electrode PE), a bank PDL, a spacer SPC, a light-emitting element LEL and an encapsulation layer ENC may be formed sequentially.

According to the method of fabricating the display device according to an embodiment of the disclosure, the active layer having different areas (e.g., the first area A1 and the second area A2 containing different amounts of nitrogen) can be formed via a single mask process using a half-tone mask. Therefore, it may be possible to form the active layer having the different areas via a single mask process so that the active layer of the switching transistor (e.g., the fourth transistor T4) contains more nitrogen than the active layer of the driving transistor (e.g., the first transistor T1). In this manner, it may be possible to fabricate a display device that can suppress leakage current of the switching transistor without compromising the current driving capability of the driving transistor, which requires high reliability, while reducing the number of processing steps.

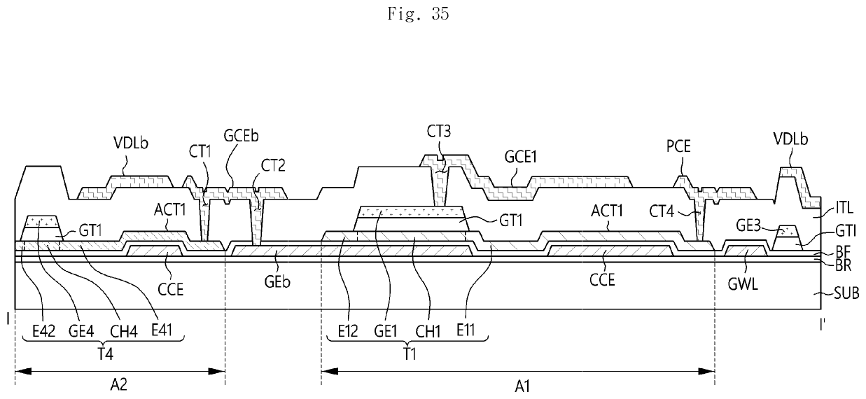

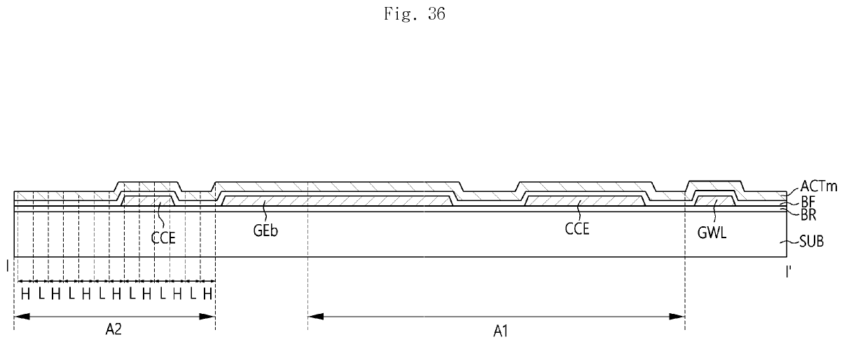

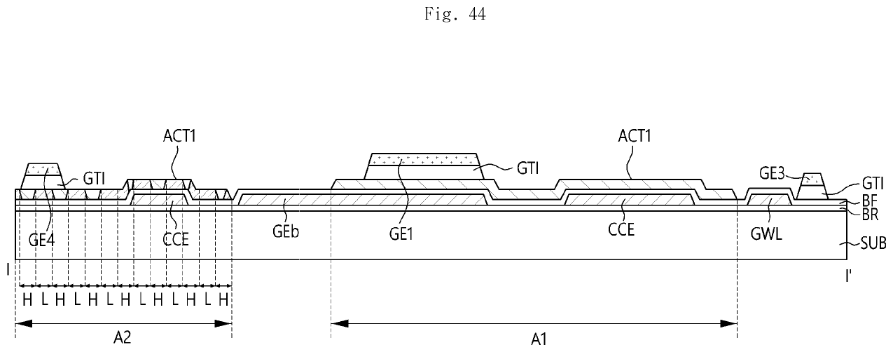

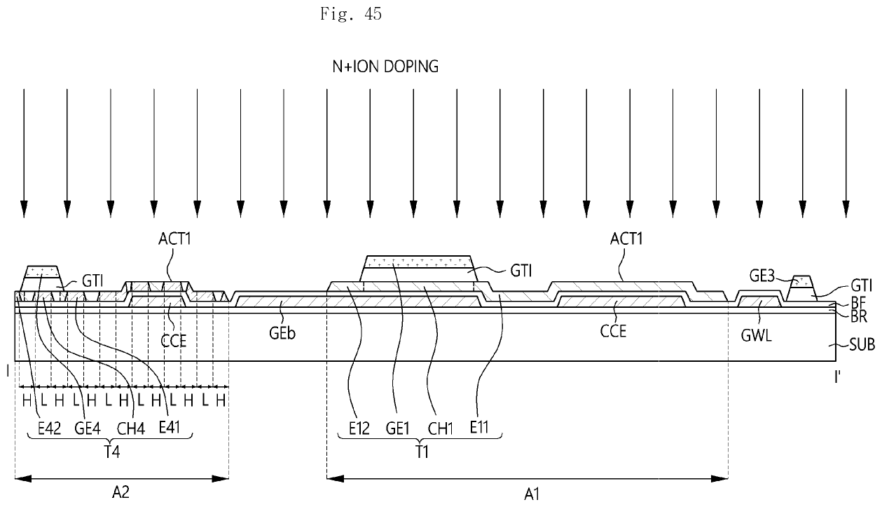

FIGS. 36 to 46 are schematic cross-sectional views showing processing steps for illustrating a method of fabricating a display device according to an embodiment of the disclosure.

Initially, as shown in FIG. 36, a substrate SUB including a first area A1 and a second area A2 is prepared. The second area A2 may include multiple first sub-areas H and multiple second sub-areas L. In other words, the second area may be divided into first sub-areas H and second sub-areas L which are arranged alternately. The first area A1 of the substrate SUB may correspond to the first area A1 of the first active layer ACT1 described above, and the second area A2 of the substrate SUB may correspond to the second area of the first active layer ACT1 described above.

Subsequently, a barrier film BR, a buffer film BUFFER and a second conductive material layer ACTm may be sequentially formed on the substrate SUB. This has been described above with reference to FIG. 23.

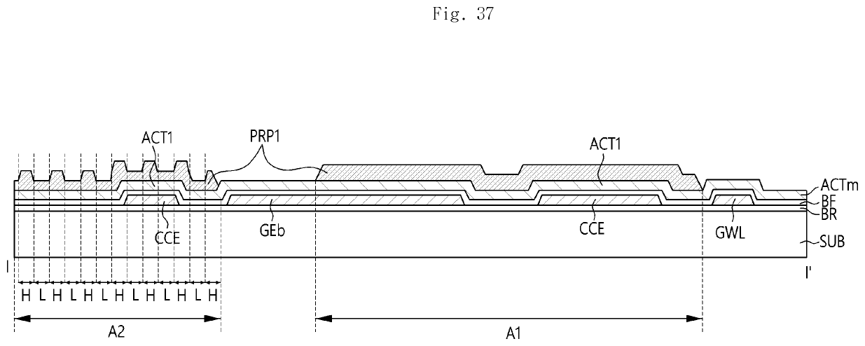

Subsequently, as shown in FIG. 37, a first photoresist pattern PRP1 having different thicknesses may be formed on the second conductive material layer ACTm. For example, the first photoresist pattern PRP1 may be formed in the first area A1, the first sub-areas H and the second sub-areas L of the first active layer ACT1, which has a larger thickness in the first area A1 and the first sub-areas H. The first photoresist pattern PRP1 may be formed via a single mask process using the above-described half-tone mask (or diffraction mask). The first photoresist pattern PRP1 may have a larger thickness in the first area A1 and the first sub-areas H among the first area A1, the first sub-areas H and the second sub-areas L of the first active layer ACT1. For example, the thickness of the first photoresist pattern PRP1 in the first area A1 may be approximately twice the thickness of the first photoresist pattern PRP1 in the second sub-areas L. The thickness of the first photoresist pattern PRP1 in the first sub-areas H may be approximately twice the thickness of the first photoresist pattern PRP1 in the second sub-areas L. Accordingly, the first photoresist pattern PRP1 in the second region A2 may have, for example, elevations. It should be noted that the thickness of the first photoresist pattern PRP1 in the first sub-areas H may be equal to the thickness of the first photoresist pattern PRP1 in the first area A1. On the other hand, the first photoresist pattern PRP1 on the second active layer ACT2 may have the same thickness as, for example, the first photoresist pattern PRP1 in the first area A1.

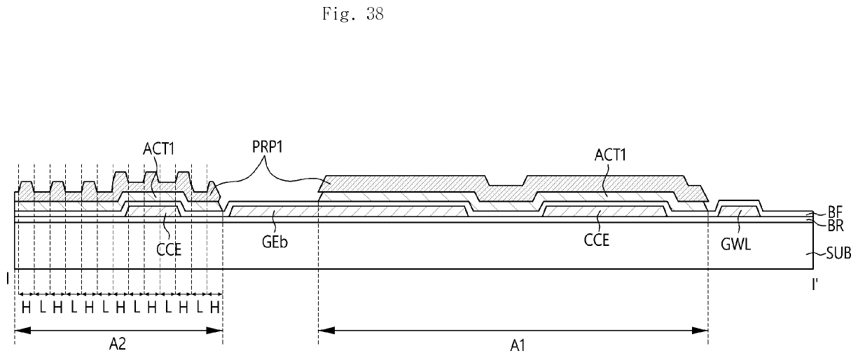

Thereafter, as shown in FIG. 38, an etching process may be carried out using the first photoresist pattern PRP1 as a mask, thereby patterning the second conductive material layer ACTm. As the second conductive material layer ACTm is patterned, the first active layer ACT1 and the second active layer ACT2 may be formed on the buffer film BF.

Subsequently, as shown in FIG. 39, an ashing process may be carried out to form a second photoresist pattern PRP2. The ashing process has been described above with reference to FIG. 27; and, therefore, redundant descriptions will be omitted. After this ashing process, the first photoresist pattern PRP1 of the first area may remain on the first area A1 of the first active layer ACT1 with a thickness of approximately half the initial thickness. The first photoresist pattern PRP1 of the first sub-areas H may remain on the first sub-areas H of the first active layer ACT1 with a thickness of approximately half the initial thickness. The first photoresist pattern PRP1 of the second active layer ACT2 may remain on the second active layer ACT2 with a thickness of approximately half the initial thickness. The first photoresist pattern PRP1 of the second sub-areas L may be removed to expose the second sub-areas L of the first active layer ACT1.

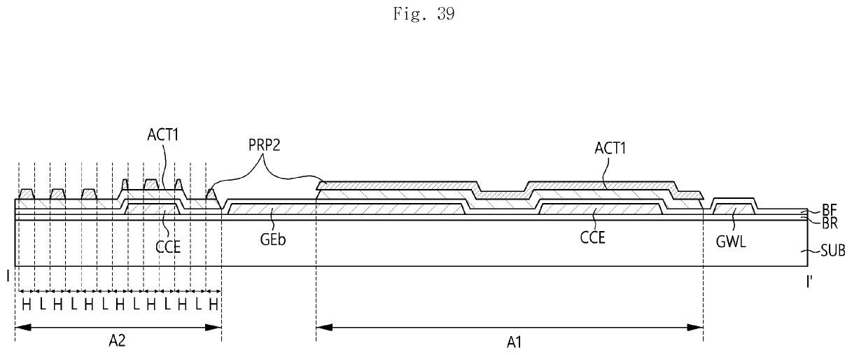

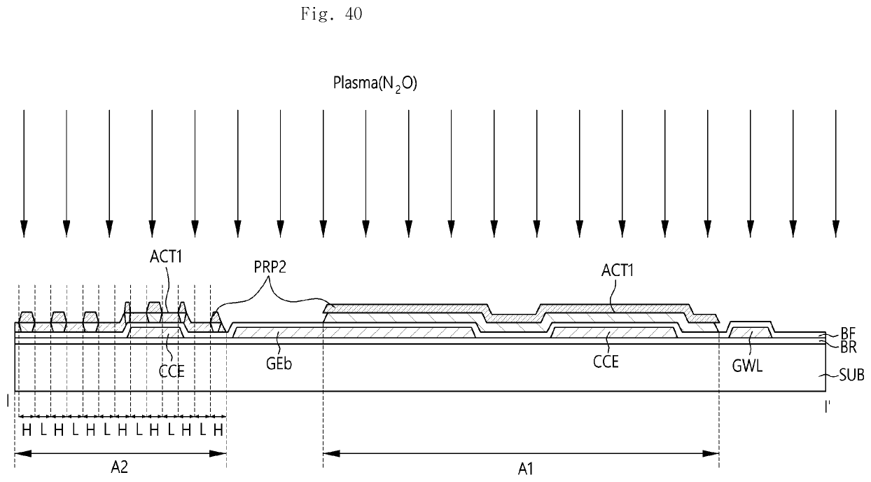

Subsequently, as shown in FIG. 40, plasma treatment may be carried out using the second photoresist pattern PRP2 as a mask. For example, plasma treatment using N₂O gas as a plasma gas may be carried out. By this plasma treatment, nitrogen may be selectively injected only in the part of the first active layer ACT1 exposed in the second sub-areas L of the second area A2. In other words, nitrogen may be selectively injected into only the second sub-areas L of the first active layer ACT1. On the other hand, no nitrogen may be injected into the first area A1 of the first active layer ACT1 and the second active layer ACT2 blocked by the second photoresist pattern PRP2.

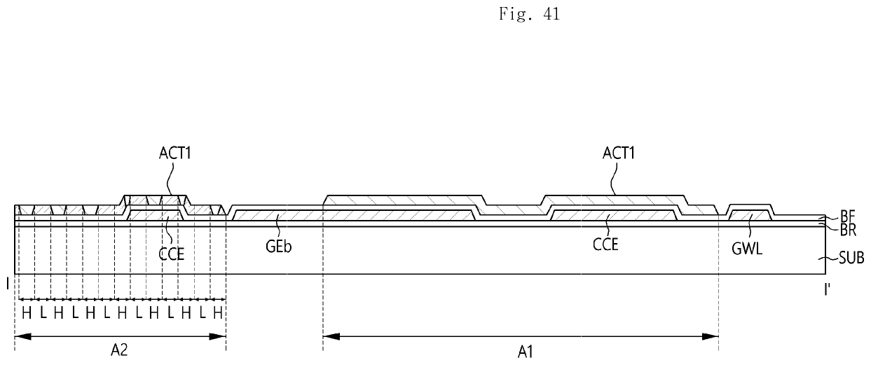

Subsequently, as shown in FIG. 41, the second photoresist pattern PRP2 may be removed via a strip process.

Subsequently, as shown in FIG. 42, an insulating material layer GTIm may be formed on the entire surface of the substrate SUB including the first active layer ACT1 and the second active layer ACT2.

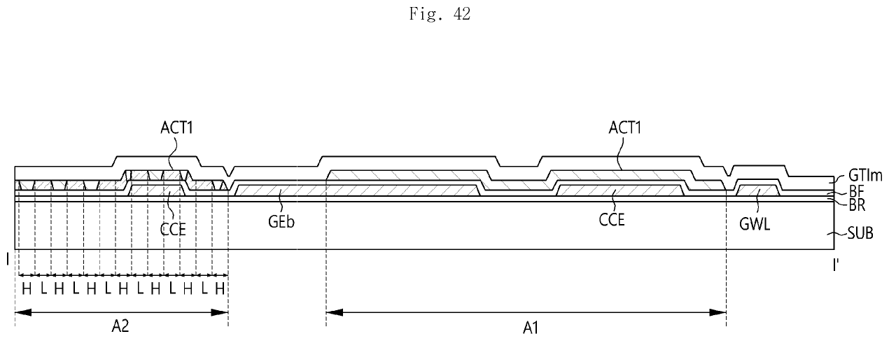

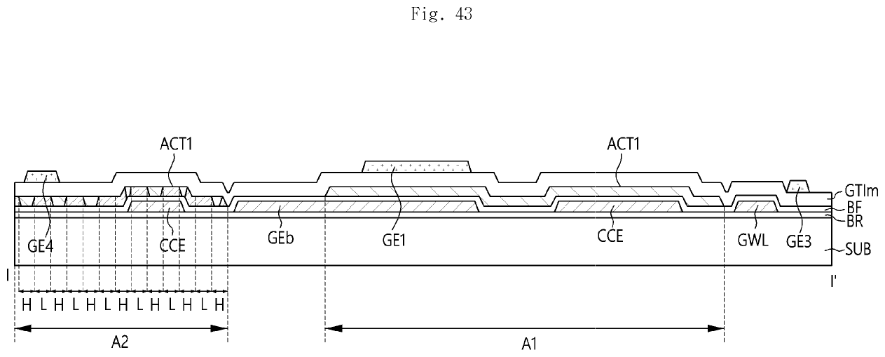

Subsequently, as shown in FIGS. 43, 44 and 45, the third conductive layer 333 and the gate insulator GTI may be formed on the substrate SUB, and an ion implantation process may be carried out using the third conductive layer 333 as a mask. The process of forming the third conductive layer 333 and the gate insulator GTI and the ion implantation process have been described above with reference to FIGS. 30 to 32; and, therefore, redundant descriptions will be omitted.

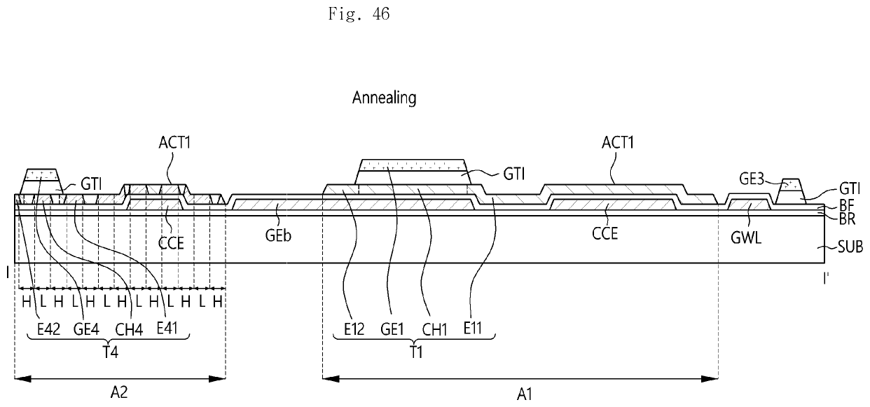

After the ion implantation process described above, as shown in FIG. 46, an annealing process may be carried out. The ions of the first active layer ACT1 and the second active layer ACT2 may be diffused to the vicinity via this annealing process. For example, the ions of the first sub-areas H and the ions of the second sub-areas L of the first active layer ACT1 may diffuse to the vicinity.

Subsequently, as shown in FIG. 14, an interlayer dielectric film ITL, first to fourth contact holes CT1 to CT4, a fourth conductive layer 444 (e.g., a first upper driving voltage line VDLb), a counter gate connection electrode GCEb, a first gate connection electrode GCE1, a pixel connection electrode PCE, a planarization film VIA, a fifth contact hole CT5, a fifth conductive layer 555 (e.g., pixel electrode PE), a bank PDL, a spacer SPC, a light-emitting element LEL, and an encapsulation layer ENC may be formed sequentially.

FIG. 47 is a schematic plan view of a pixel array of a display device including the pixel circuits PC of FIG. 5 according to an embodiment of the disclosure. FIG. 48 is a schematic cross-sectional view taken along line I-I′ of FIG. 47. FIG. 47 shows a second conductive layer according to another embodiment.

As shown in FIG. 47, the second conductive layer 222 may include a first active layer ACT1, a second active layer ACT2 and a third active layer ACT3 physically separated from one another.

The first active layer ACT1 may form a first transistor T1 and a fifth transistor T5 together with a first gate electrode GE1 and a fifth gate electrode GE5, respectively.

The second active layer ACT2 may form second and third transistors T2 and T3 together with the second and third gate electrodes GE2 and GE3. For example, as shown in FIG. 47, the second active layer ACT2 may include a first electrode E21 of the second transistor T2, a second electrode E22 of the second transistor T2, a second channel region CH2 of the second transistor T2, a first electrode E31 of the third transistor T3, a second electrode E32 of the third transistor T3, and a third channel region CH3 of the third transistor T3.

The third active layer ACT3 may form the fourth transistor T4 together with the fourth gate electrodes GE4. For example, as shown in FIG. 47, the third active layer ACT3 may include a first electrode E41 of the fourth transistor T4, a second electrode E42 of the fourth transistor T4, and a fourth channel region CH4 of the transistor T4.

The second active layer ACT2 of FIG. 47 may be identical to the second active layer ACT2 of FIGS. 6A and 8 described above. The first active layer ACT1 and the third active layer ACT3 of FIG. 47 may be different from the second active layer ACT2 of FIGS. 6A and 8 at least in that they are separated from each other.

The nitrogen content of the third active layer ACT3 may be greater than that of the first active layer ACT1. In this instance, the nitrogen content of the first active layer ACT1 may be zero, and the nitrogen content of the third active layer ACT3 may be greater than zero.

The nitrogen content of the third active layer ACT3 may be greater than that of the second active layer ACT2. In this instance, the nitrogen content of the second active layer ACT2 may be zero, and the nitrogen content of the third active layer ACT3 may be greater than zero.

The first active layer ACT1 and the third active layer ACT3 may be connected to each other through the fifth conductive layer 555 on the interlayer dielectric film ITL, for example, an active connection electrode ACE. As shown in FIG. 48, the active connection electrode ACE may be connected to the first electrode E11 of the first active layer ACT1 through a sixth contact hole CT6 penetrating the interlayer dielectric film ITL. The active connection electrode ACE may be connected to the first electrode E41 of the third active layer ACT3 through a seventh contact hole CT7 penetrating the interlayer dielectric film ITL. The sixth contact hole CT6 and the seventh contact hole CT7 may belong to the first-type contact holes described above.

The third active layer ACT3 may include, for example, polycrystalline silicon or oxide. For example, in case that the third active layer ACT3 includes oxide, the third active layer ACT3 may be oxide semiconductor that includes indium-gallium-zinc-oxide (IGZO) or indium-gallium-zinc-tin oxide (IGZTO).

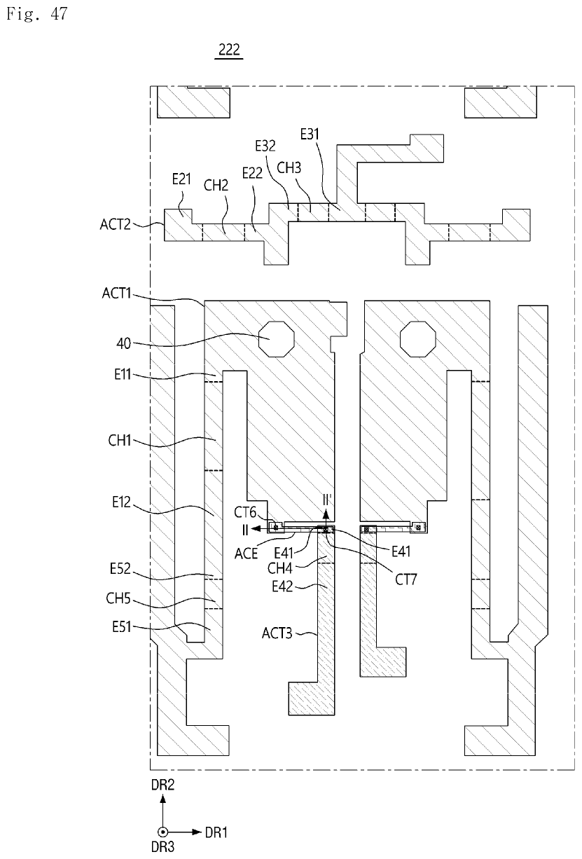

FIGS. 49 to 52 are schematic cross-sectional views showing processing steps for illustrating a method of fabricating a display device according to an embodiment of the disclosure.

Initially, as shown in FIG. 49, a barrier film BR and a buffer film BF may be formed on a substrate SUB. For example, the barrier film BR and the buffer film BF may be formed on the entire surface of the substrate SUB.

Subsequently, a (2-1) conductive material layer may be formed on the entire surface of the substrate SUB including the buffer film BF, and the (2-1) conductive material layer may be patterned via a photolithography process and an etching process. The (2-1) conductive material layer may be, for example, a semiconductor material such as the indium-gallium-zinc-oxide (IGZO) containing nitrogen and the indium-gallium-zinc-tin-oxide containing nitrogen (IGZTO) containing nitrogen. As shown in FIG. 49, as the (2-1) conductive material layer is patterned, the third active layer ACT3 containing nitrogen may be formed on the buffer film BF.

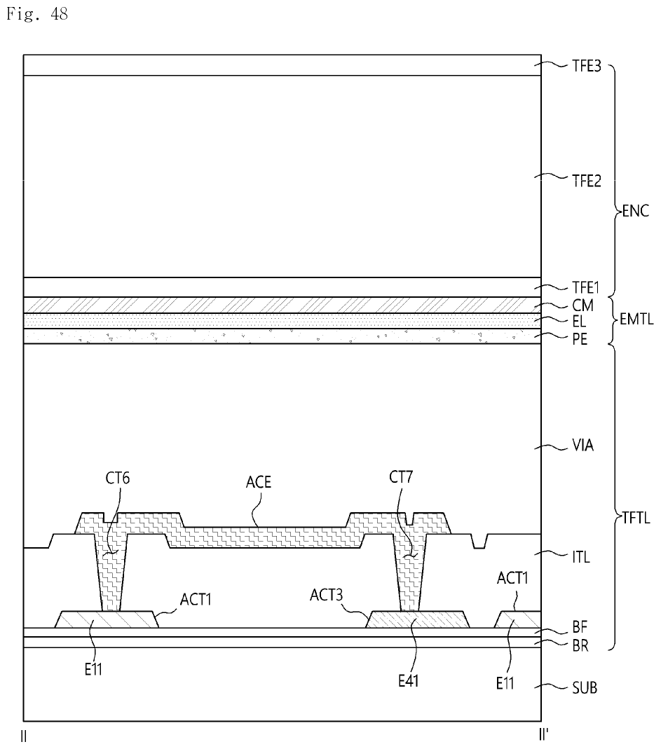

Subsequently, a (2-2) conductive material layer may be formed on the entire surface of the substrate SUB including the buffer film BF, and the (2-2) conductive material layer may be patterned via a photolithography process and an etching process. The (2-2) conductive material layer may be, for example, a semiconductor material such as the indium-gallium-zinc-oxide (IGZO) containing no nitrogen and the indium-gallium-zinc-tin-oxide containing nitrogen (IGZTO) containing no nitrogen. As the (2-2) conductive material layer is patterned, the first active layer ACT1 and the second active layer ACT2 containing no nitrogen may be formed on the buffer film BF as shown in FIG. 50.

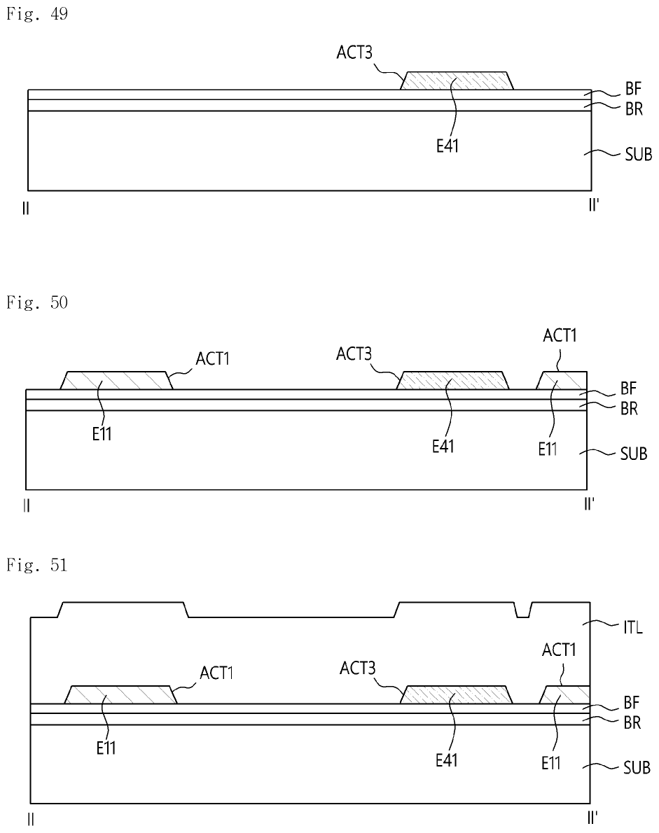

Subsequently, as shown in FIG. 51, an interlayer dielectric film ITL may be formed on the entire surface of the substrate SUB.

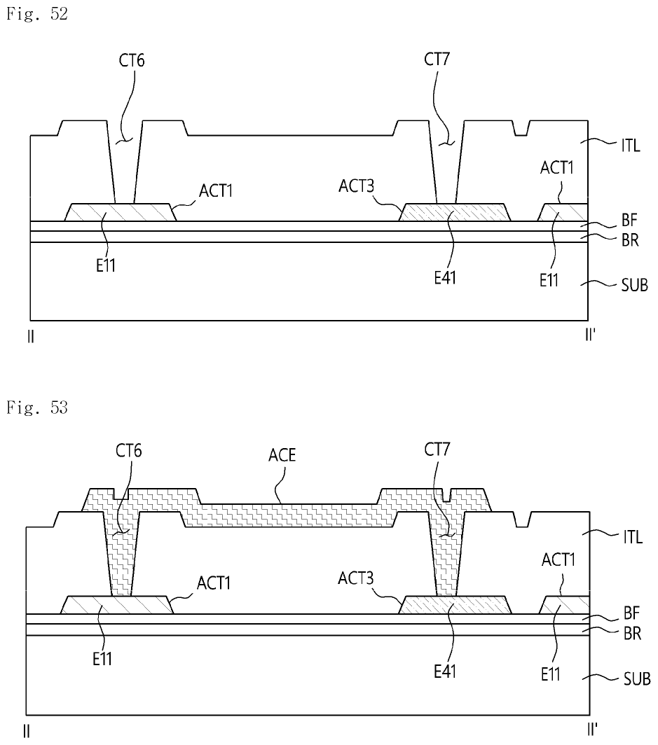

Subsequently, as shown in FIG. 52, a sixth contact hole CT6 and a seventh contact hole CT7 penetrating the interlayer dielectric film ITL may be formed via a photolithography and etching process. The first electrode E11 of the first active layer ACT1 may be exposed by the sixth contact hole CT6, and the first electrode E41 of the third active layer ACT3 may be exposed by the seventh contact hole CT7.

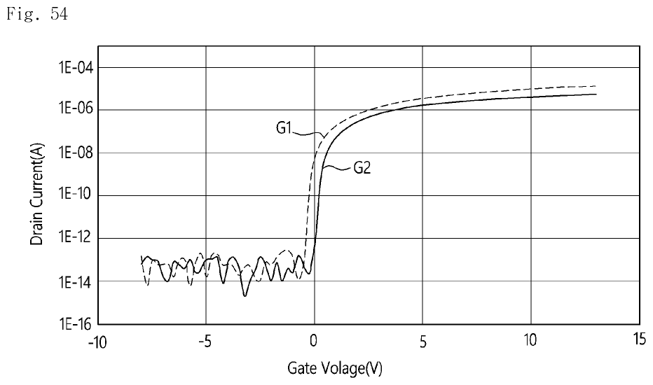

Subsequently, a fourth conductive material layer may be formed on the entire surface of the substrate SUB including the interlayer dielectric film ITL, and the fourth conductive material layer may be patterned via a photolithography process and an etching process. As the fourth conductive material layer is patterned, the fourth conductive layer 444, for example, as shown in FIG. 53, the active connection electrode ACE may be formed on the interlayer dielectric film ITL. In this instance, the active connection electrode ACE may be connected to the first electrode E11 of the first active layer ACT1 through the sixth contact hole CT6, and may be connected to the first electrode E41 of the third active layer ACT3 through the seventh contact hole CT7.

Subsequently, on the fourth conductive layer 444 (e.g., the active connection electrode ACE), as shown in FIG. 48, a planarization film VIA, a pixel electrode PE, a bank PDL, a spacer SPC, and a light-emitting element LEL and an encapsulation layer ENC may be formed sequentially.

FIG. 54 is a schematic graph for illustrating effects of the disclosure.

The graph shown in FIG. 54 may include transistor characteristic curves showing the magnitude of drain current versus gate voltage of a transistor. For example, a first curve G1 is a characteristic curve of a transistor including an active layer containing no nitrogen (hereinafter referred to as a transistor according to Comparative Example), while a second curve G2 is a characteristic curve of a transistor including an active layer containing nitrogen (hereinafter referred to as a transistor according to an embodiment of the disclosure).

As shown in FIG. 54, the transistor according to the embodiment of the disclosure can flow a smaller drain current at the same gate voltage than the transistor according to Comparative Example. In other words, since the transistor according to the embodiment of the disclosure can have a larger threshold voltage due to the nitrogen implanted by the plasma treatment, the leakage current of the transistor according to the embodiment of the disclosure (e.g., the fourth transistor T4) can be suppressed.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a first transistor;
a pixel electrode electrically connected to the first transistor; and
a second transistor electrically connected to the first transistor,
wherein a nitrogen content per unit area of an active layer of the second transistor is greater than a nitrogen content per unit area of an active layer of the first transistor.

2. The display device of claim 1, wherein
the active layer comprises:
a first channel region of the first transistor; and
a second channel region of the second transistor, and
a nitrogen content per unit area of the second channel region is greater than a nitrogen content per unit area of the second channel region.

3. The display device of claim 1, wherein
the active layer comprises:
a first source region of the first transistor;
a first drain region of the first transistor;
a second source region of the second transistor; and
a second drain region of the second transistor, and
a nitrogen content per unit area of the second source region is greater than a nitrogen content per unit area of the first source region.

4. The display device of claim 3, wherein a nitrogen content per unit area of the second drain region is greater than a nitrogen content per unit area of the first drain region.

5. The display device of claim 1, wherein
the active layer comprises:
a first active layer overlapping a first gate electrode of the first transistor in a plan view; and
a second active layer overlapping a second gate electrode of the second transistor in plan view, and
a nitrogen content per unit area of the second active layer is greater than the nitrogen content per unit area of the first active layer.

6. The display device of claim 4, wherein the first active layer and the second active layer are disposed on a same layer.

7. The display device of claim 1, wherein a threshold voltage of the second transistor is greater than a threshold voltage of the first transistor.

8. The display device of claim 1, wherein the active layer further comprises at least one of indium-gallium-zinc oxide and indium-gallium-zinc-tin oxide.

9. A display device, comprising:
an active layer;
a first transistor comprising a first gate electrode overlapping a first channel region of the active layer in plan view;
a second transistor comprising a second gate electrode overlapping a second channel region of the active layer in plan view; and
a pixel electrode electrically connected to the first transistor,
wherein a nitrogen content per unit area of the second channel region is greater than a nitrogen content per unit area of the first channel region.

10. The display device of claim 9, wherein
the active layer comprises:
a first source region of the first transistor;
a first drain region of the first transistor;
a second source region of the second transistor; and
a second drain region of the second transistor, and
a nitrogen content per unit area of the second source region is greater than a nitrogen content per unit area of the first source region.

11. The display device of claim 10, wherein a nitrogen content per unit area of the second drain region is greater than a nitrogen content per unit area of the first drain region.

12. A method of fabricating a display device, the method comprising:
forming an active material layer on a substrate comprising a first area and a second area;
forming a first photoresist pattern having a larger thickness in the first area among the first and second areas and on the active material layer;
patterning the active material layer using the first photoresist pattern as a mask to form active layers;
forming a second photoresist pattern by removing a part of the first photoresist pattern in line with the second area;
providing nitrogen to a part of the active layer exposed in the second area using the second photoresist pattern as a mask;
forming a first transistor comprising a gate electrode overlapping the active layer of the first area in plan view;
forming a second transistor comprising a gate electrode overlapping the active layer of the second area in plan view; and
forming a pixel electrode electrically connected to the first transistor.

13. The method of claim 12, wherein the providing of nitrogen comprises:
providing nitrogen to the part of the active layer of the second area exposed by the second photoresist pattern using N₂O as a plasma gas.

14. The method of claim 13, wherein the active layer of the first area comprises:
a channel region of the first transistor;
a source region of the first transistor; and
a drain region of the first transistor.

15. The method of claim 13, wherein the active layer of the second area comprises:
a channel region of the second transistor;
a source region of the second transistor; and
a drain region of the second transistor.

16. A method of fabricating a display device, the method comprising:
preparing a substrate comprising a second area comprising first sub-areas and second sub-areas, and a first area;
forming an active material layer on the substrate;
forming a first photoresist pattern on the active material layer, the first photoresist pattern having a larger thickness formed in the first area and the first sub-areas among the first area, the first sub-areas and the second sub-areas;
patterning the active material layer using the first photoresist pattern as a mask to form active layers;
forming a second photoresist pattern by removing parts of the first photoresist pattern in line with the second area and the second sub-area;
providing nitrogen to parts of the active layer exposed in the second area and the second sub-areas using the second photoresist pattern as a mask;
forming a first transistor comprising a gate electrode overlapping the active layer of the first area in plan view;
forming a second transistor comprising a gate electrode overlapping the active layer of the second area in plan view; and
forming a pixel electrode electrically connected to the first transistor.

17. The method of claim 16, further comprising:
after the providing of nitrogen:
removing the second photoresist pattern; and
annealing the substrate comprising the active layer.

18. The method of claim 16, wherein the active layer of the first area comprises:
a channel region of the first transistor;
a source region of the first transistor; and
a drain region of the first transistor.

19. The method of claim 16, wherein the active layer of the second area comprises:
a channel region of the second transistor;
a source region of the second transistor; and
a drain region of the second transistor.

20. A method of fabricating a display device, the method comprising:
forming a first active layer containing nitrogen on a substrate;
forming a second active layer on the substrate;
forming a first transistor comprising a gate electrode overlapping the second active layer in plan view;
forming a second transistor comprising a gate electrode overlapping the first active layer in plan view; and
forming a pixel electrode electrically connected to the first transistor.

21. The method of claim 20, wherein the first active layer comprises:
a channel region of the second transistor;
a source region of the second transistor; and
a drain region of the second transistor.

22. The method of claim 20, wherein the second active layer comprises:
a channel region of the first transistor;
a source region of the first transistor; and
a drain region of the first transistor.
